(19) United States
(12) Patent Application Publication
(10) Pub. No.: US 2022/0180029 A1
(43) Pub. Date: Jun. 9, 2022

(54) Generating Values For Property Parameters

(71) Applicant: CHEVRON U.S.A. INC., San Ramon, CA (US)

(72) Inventors: Yuanbo LIN, Midland, TX (US); Hussein ALBOUDWAREJ, San Ramon, CA (US); Baosheng LIANG, Houston, TX (US)

(73) Assignee: CHEVRON U.S.A. INC., San Ramon, CA (US)

(21) Appl. No.: 17/543,287

(22) Filed: Dec. 6, 2021

Related U.S. Application Data
(60) Provisional application No. 63/121,587, filed on Dec. 4, 2020.

(51) Int. Cl. G06F 30/28

(52) U.S. Cl. CPC G06F 30/28

(57) ABSTRACT

Embodiments of generating values for property parameters are provided. One embodiment comprises obtaining values for a plurality of samples. The values correspond to a set of property parameters. The embodiment comprises identifying a first subset of property parameters from the set of property parameters that correlate to substantially all property parameters of the set of property parameters; and generating at least one model using the first subset of property parameters and a database corresponding to the at least one model, and using the at least one model for generating a value for at least one other property parameter of the set of property parameters. The first subset of property parameters and the at least one other property parameter are different. Another embodiment comprises generating a value for at least one other property for an additional sample using the at least one model.

### CROSS-REFERENCE TO RELATED APPLICATIONS

This application claims benefit of U.S. Provisional Application No. 63/121,587, filed Dec. 4, 2020, which is hereby incorporated by reference in its entirety.

### STATEMENT REGARDING FEDERALLY SPONSORED RESEARCH OR DEVELOPMENT

Not applicable.

### TECHNICAL FIELD

The disclosed embodiments relate generally to techniques for generating values for property parameters.

### BACKGROUND

Understanding fluid phase behavior in the unconventional reservoir through systematic and proper pressure volume temperature (PVT) sampling and fluid characterization are important in many aspects, such as: (1) fluid properties for electrical resistance tomography (ERT), discovered resources opportunities (DRO) and reserves, and geological neighborhood delineation for type curve; (2) well spacing, completion designs, and well performance forecasting; (3) choke size management, artificial lift optimization, and geomechanics; (4) facilities, commercials, and enhanced oil recovery (EOR).

Unfortunately, access to representative live/reservoir fluid samples from unconventional plays, and thus having a reliable source of fluid properties information, is very challenging. Access to such information is made more difficult by the frequent drilling and completion of new wells in unconventional reservoirs. Moreover, fracture fluids used for hydraulic fracturing and the nano size pores of unconventional reservoirs further complicate fluid sampling and production behavior.

As a result, the conventional approach uses a) assumptions based on nearby analog wells or b) performs PVT sampling and analysis to determine fluid property data. This approach is generally not accurate in the case of the former, or costly and time consuming for the latter.

There exists a need in the area of generating values for property parameters.

### SUMMARY

In accordance with some embodiments, a method of generating values for property parameters is provided herein. In one embodiment, the method comprises: obtaining values for a plurality of samples, wherein the values correspond to a set of property parameters; identifying a first subset of property parameters from the set of property parameters that correlate to substantially all property parameters of the set of property parameters; and generating at least one model using the first subset of property parameters and a database corresponding to the at least one model, and using the at least one model for generating a value for at least one other property parameter of the set of property parameters, wherein the first subset of property parameters and the at least one other property parameter are different.

In another aspect of the present invention, to address the aforementioned problems, some embodiments provide a non-transitory computer readable storage medium storing one or more programs. The one or more programs comprise instructions, which when executed by a computer system with one or more processors and memory, cause the computer system to perform any of the methods provided herein. In one embodiment, a non-transitory computer readable storage medium storing one or more programs, the one or more programs comprising instructions, which when executed by an electronic device with one or more processors and memory, cause the device to execute the method of: obtaining values for a plurality of samples, wherein the values correspond to a set of property parameters; identifying a first subset of property parameters from the set of property parameters that correlate to substantially all property parameters of the set of property parameters; and generating at least one model using the first subset of property parameters and a database corresponding to the at least one model, and using the at least one model for generating a value for at least one other property parameter of the set of property parameters, wherein the first subset of property parameters and the at least one other property parameter are different.

In yet another aspect of the present invention, to address the aforementioned problems, some embodiments provide a computer system. The computer system includes one or more processors, memory, and one or more programs. The one or more programs are stored in memory and configured to be executed by the one or more processors. The one or more programs include an operating system and instructions that when executed by the one or more processors cause the computer system to perform any of the methods provided herein. In one embodiment, a system of generating values for property parameters comprises: one or more physical processors configured by machine-readable instructions to execute the method of: obtaining values for a plurality of samples, wherein the values correspond to a set of property parameters; identifying a first subset of property parameters from the set of property parameters that correlate to substantially all property parameters of the set of property parameters; and generating at least one model using the first subset of property parameters and a database corresponding to the at least one model, and using the at least one model for generating a value for at least one other property parameter of the set of property parameters, wherein the first subset of property parameters and the at least one other property parameter are different.

### BRIEF DESCRIPTION OF THE DRAWINGS

FIG. 1 illustrates one embodiment of a method 90 of generating values for property parameters.

FIG. 2 illustrates one embodiment of block 110 of FIG. 1.

FIG. 3 illustrates one example of block 1102 in FIG. 2.

FIG. 4 illustrates one example of block 1104 in FIG. 2.

FIG. 5 illustrates one example of block 1106 in FIG. 2.

FIG. 6 illustrates one embodiment of block 120 in FIG. 1.

FIG. 7 illustrates one example of block 1202 in FIG. 6.

FIG. 8 illustrates one example of block 1204 in FIG. 6.

FIG. 9 illustrates one example of block 1206 in FIG. 6 and one example of block 1208 in FIG. 6.

FIG. 10 illustrates one example of block 1210 in FIG. 6.

FIG. 11 illustrates one example of block 1212 in FIG. 6.

FIG. 12 illustrates one embodiment of block 130 in FIG. 1.

FIG. 13 illustrates one example of block 1302 in FIG. 12.

FIG. 14 illustrates one example of block 1304 in FIG. 12, block 1306 in FIG. 12, and block 1308 in FIG. 12.

FIG. 15 illustrates one example of block 1310 in FIG. 12.

FIG. 16 illustrates one embodiment of the method 200 of generating values for property parameters.

FIG. 17 illustrates one embodiment of block 220 in FIG. 16.

FIG. 18 illustrates one example of block 2202 in FIG. 17.

FIG. 19 illustrates one example of block 2204 in FIG. 17.

FIG. 20 illustrates one example of block 2206 in FIG. 17, block 2208 in FIG. 17, and block 2210 in FIG. 17.

FIG. 21 illustrates one example of block 2212 in FIG. 17.

FIG. 22 illustrates one embodiment of block 230 in FIG. 16.

FIG. 23 illustrates one example of block 2301 in FIG. 22.

FIG. 24 illustrates one example of block 2302 in FIG. 22.

FIG. 25 illustrates one example of block 2303 in FIG. 22.

FIG. 26 illustrates one example of block 2304 in FIG. 22.

FIG. 27 illustrates one example of block 2305 in FIG. 22 and block 2306 in FIG. 22.

FIG. 28 illustrates one example of block 2307 in FIG. 22.

FIG. 29 illustrates one example of block 2308 in FIG. 22 and block 2309 in FIG. 22.

FIG. 30 illustrates one embodiment of block 240 in FIG. 16.

FIG. 31 illustrates one example of block 2401 in FIG. 30.

FIG. 32 illustrates one example of block 2402 in FIG. 30.

FIG. 33 illustrates one example of block 2403 in FIG. 30.

FIG. 34 illustrates one example of block 2404 in FIG. 30 and block 2405 in FIG. 30.

FIG. 35 illustrates one example of block 2406 in FIG. 30.

FIG. 36 illustrates a second embodiment of block 240 in FIG. 16.

FIG. 37 illustrates one example of block 2408 in FIG. 36 and block 2409 in FIG. 36.

FIG. 38 illustrates one example of block 2407 in FIG. 36.

FIG. 39 illustrates one embodiment of block 250 in FIG. 16.

FIG. 40A illustrates one embodiment of a system of generating values for property parameters.

FIG. 40B illustrates another embodiment of a system of generating values for property parameters.

### DETAILED DESCRIPTION

Provided herein are embodiments of generating values for property parameters. Advantageously, reliable fluid property correlations may be generated to provide apriori knowledge of fluid properties using minimum production data or analog information input, enabling exploration and field development activities without extended time to collect and analyze fluid samples. Indeed, costs (e.g., monetary and time) may be reduced while achieving early access to critical fluid property information for well test design and operational considerations.

Advantageously, embodiments consistent with the instant disclosure may reduce uncertainties associated with fluid sampling, and fluid property measurements through (a) easier sampling process and lower sampling errors and/or (b) high certainty of GOR determination for successive fluids re-combination.

Advantageously, embodiments consistent with the instant disclosure may lead to cost saving in fluid sampling and lab tests through straightforward lab measurement and shorter lab test turnaround.

Advantageously, embodiments consistent with the instant disclosure may improve prediction accuracy of fluid properties from customized fluid property correlations through fit-for-purpose correlation construction from machine learning technique.

Advantageously, embodiments consistent with the instant disclosure may be utilized to identify good PVT samples (here, “good” means sample acquired from reliable testing/measurements”), build intrinsic correlations and forecast PVT properties from limited information: Process to QAQC PVT samples and to construct a reliable and trustworthy database/information pool for model construction, data analysis and property forecast; Methodology to identify systematic bias from PVT sampling to ensure the data quality in the database/information pool; Machine learning to identify the intrinsic correlation if any amongst compositions to avoid exhaustive composition analysis or GOR measurements needed; Machine learning to categorize new PVT samples to existing groups or new group; and/or Correlation constructed as aforementioned can be used to: (a) Forecast PVT properties with limited inputs from lab/field measurement; and/or (b) QAQC lab measurements (application).

Advantageously, embodiments consistent with the instant disclosure may allow fluid property correlation to be built via machine learning techniques to: Accurately identify the key driver(s) for accurate PVT property prediction; Candidate module terms generate from trend analysis through machine learning models; and/or Automatic search and identify the optimal correlation expressions from artificial intelligence.

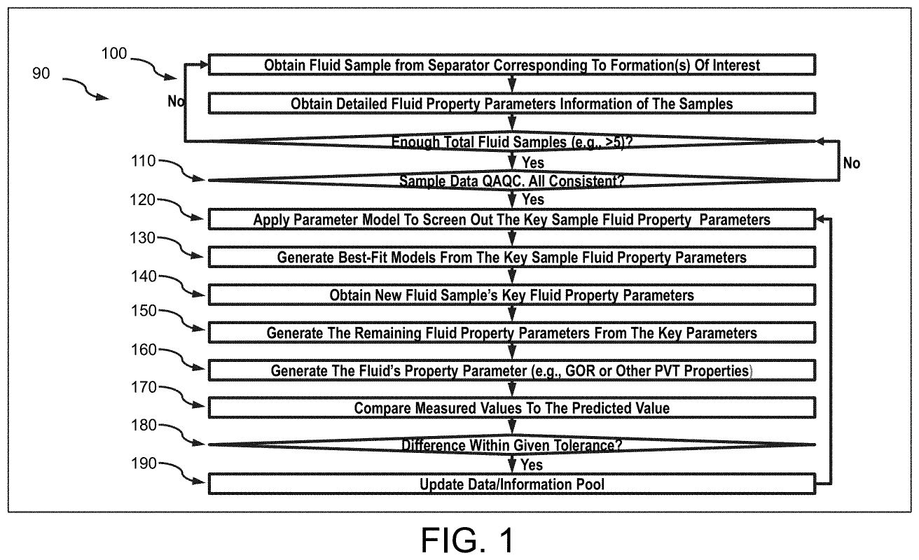

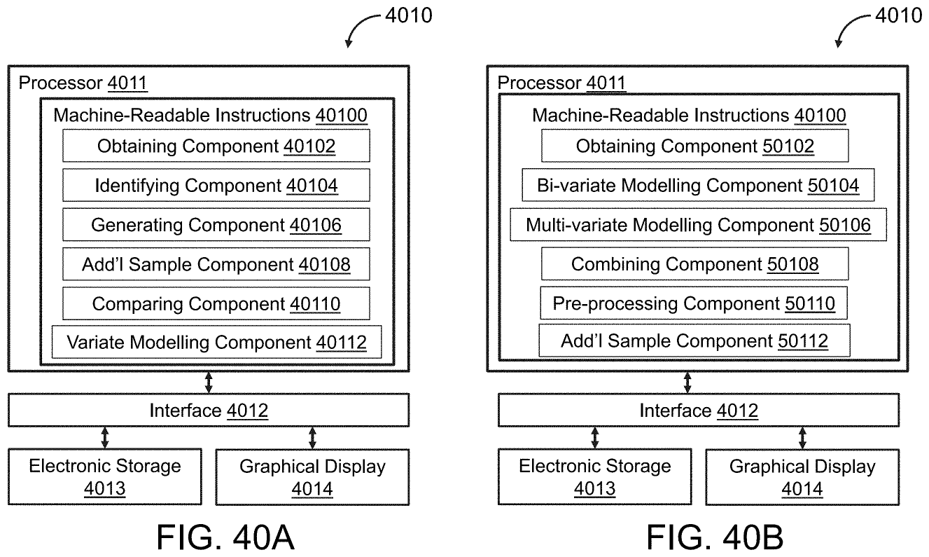

One embodiment of a method of generating values for property parameters is provided in the accompanying figures as a method 90 in FIG. 1. Although fluid samples, unconventional reservoirs, hydraulic fracturing, and the like are mentioned herein, the claims are not limited to these. Additionally, for ease of understanding, some non-limiting examples will be references in connection with the method 90. The method 90 may be executed by a system, such as a computing system (e.g., at least one computer) as illustrated in FIGS. 40A-40B. The method 90 may be utilized for data screening and validation for reliable fluid property parameter identification.

The method 90 includes obtaining values for a plurality of samples (e.g., see block 100 in FIG. 1). The values correspond to a set of property parameters. Obtaining values includes receiving, accessing, requesting, or practically any manner of obtaining data. Examples of property parameters include, but are not limited to, composition, gas oil ratio (GOR), condensate gas ratio (CGR), water oil ratio (WOR), water gas ratio (WGR), density, viscosity, compressibility, Young modulus, geochemical characterization, or any combination thereof.

In some embodiments, the values are obtained for a plurality of fluid samples, and wherein the values correspond to a set of fluid property parameters. In some embodiments, the plurality of fluid samples comprises an oil sample from a separator, a gas sample from a separator, or any combination thereof. The term “fluid” refers to liquid and gaseous phases.

In some embodiments, the values are obtained for a plurality of fluid samples and solid samples, and wherein the values correspond to a set of fluid and solid property parameters. In some embodiments, the plurality of fluid samples and solid samples comprises an oil sample from a separator, a gas sample from a separator, or any combination thereof. A solid sample may be a core sample, a rock sample, or practically any other solid sample in the hydrocarbon industry such as a solid sample from heavy oil.

In some embodiments, the values are obtained for a plurality of solid samples, and wherein the values correspond to a set of solid property parameters.

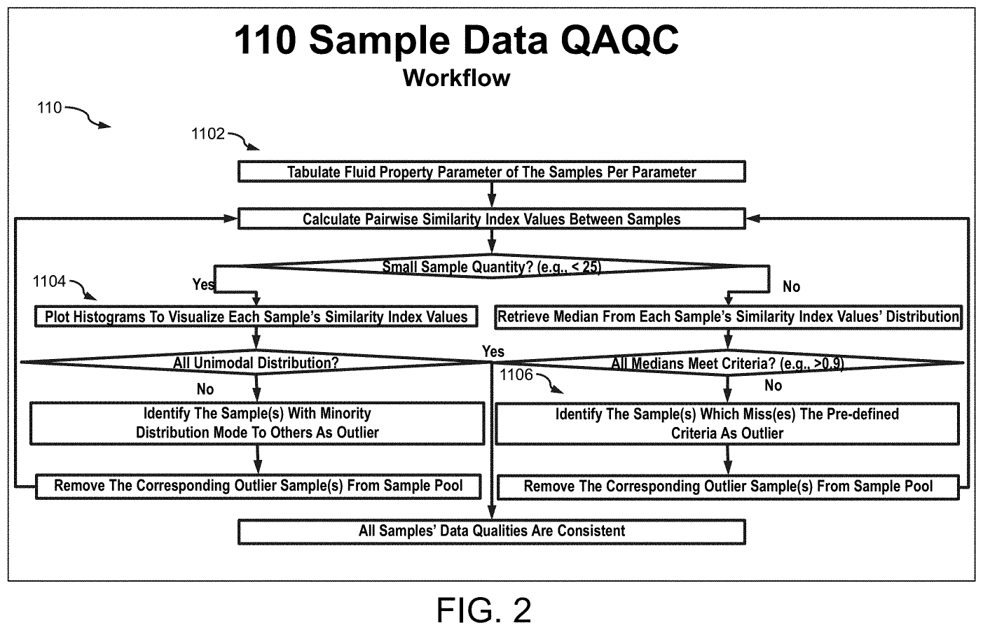

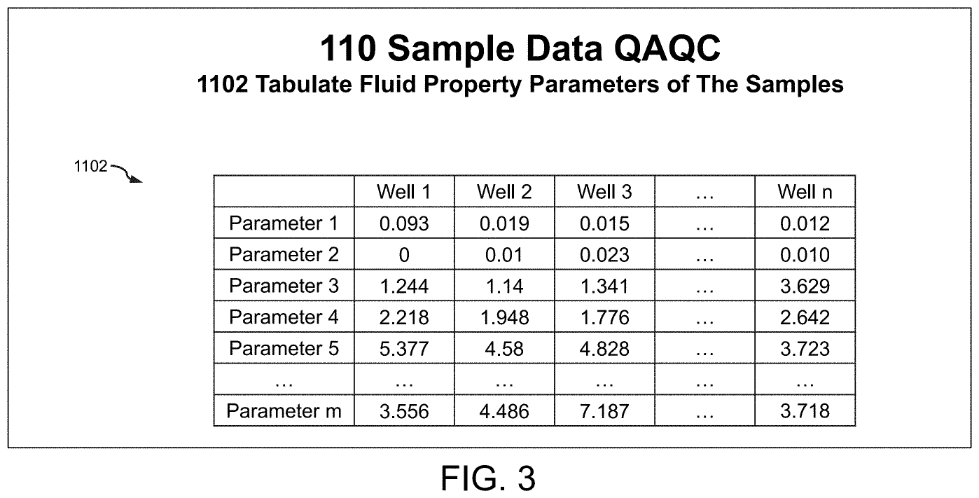

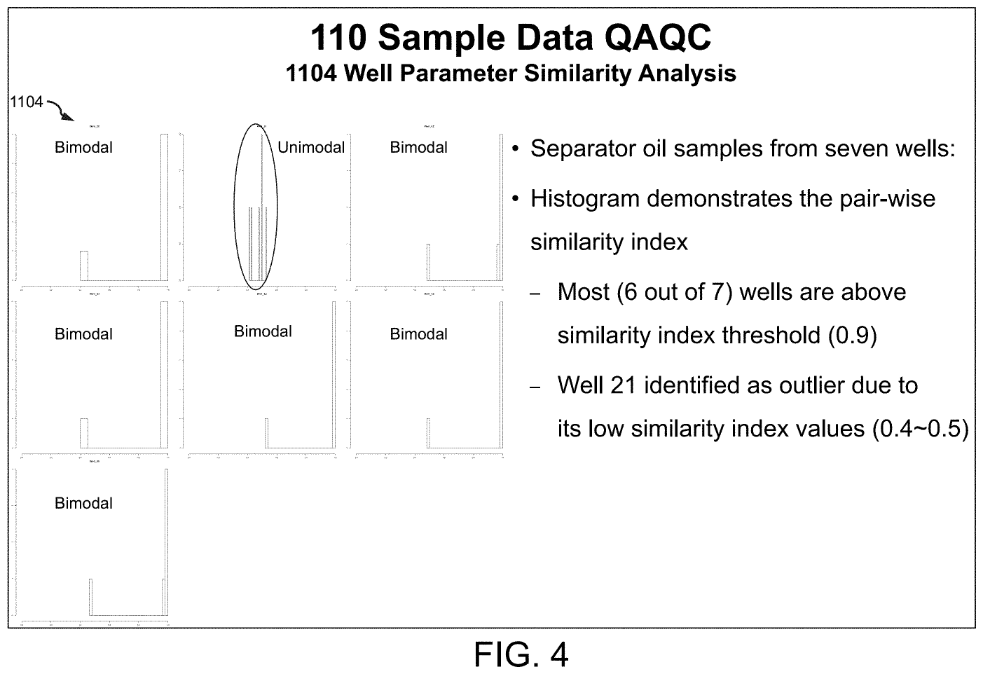

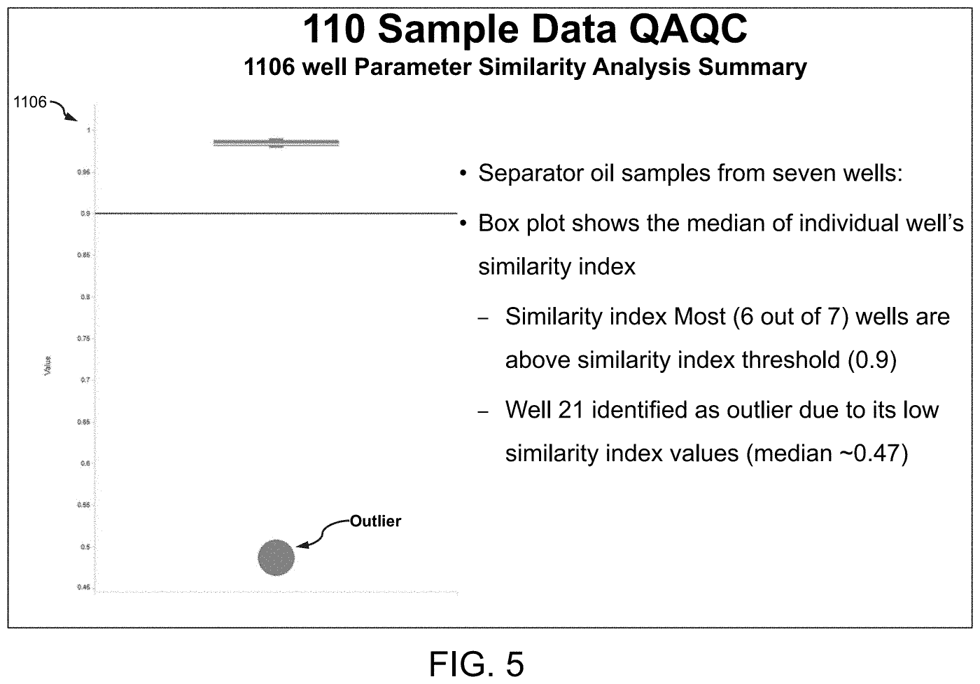

In some embodiments, at least a portion of the obtained values for the plurality of samples satisfy quality criteria. In some embodiments, the quality criteria comprises measurement error, first principles, constraint by physics of a subsurface region, acquisition of the plurality of samples, thermodynamic consistency of the plurality of samples, quantity of the plurality of samples, or any combination thereof (e.g., see blocks 100-110 in the figures). Acquisition of the plurality of samples may include timing of the acquisition, acquisition procedure/acquisition methodology, acquisition conditions, etc. FIG. 2 illustrates one embodiment of block 110 in FIG. 1 related to quality assurance and quantity control (QAQC). FIG. 3 illustrates one example of block 1102 in FIG. 2. FIG. 4 illustrates one example of block 1104 in FIG. 2. FIG. 5 illustrates one example of block 1106 in FIG. 2.

The method 90 includes identifying a first subset of property parameters from the set of property parameters that correlate to substantially all property parameters of the set of property parameters (e.g., see block 120 in the figures). In the figures, the term “key parameters” and the like may refer to the first subset of property parameters that is identified. Substantially all property parameters of the set of property parameters includes all of the property parameters of the set of property parameters in one embodiment. Substantially all property parameters of the set of property parameters includes 90% to 100% of all of the property parameters of the set of property parameters in another embodiment. Substantially all property parameters of the set of property parameters includes 80% to 100% of all of the property parameters of the set of property parameters in another embodiment. Substantially all property parameters of the set of property parameters includes 70% to 100% of all of the property parameters of the set of property parameters in another embodiment. Substantially all property parameters of the set of property parameters includes 60% to 100% of all of the property parameters of the set of property parameters in another embodiment. Substantially all property parameters of the set of property parameters includes 51% to 100% of all of the property parameters of the set of property parameters in another embodiment.

In some embodiments, identifying the first subset of property parameters from the set of property parameters that correlate to substantially all property parameters of the set of property parameters comprises using correlation criteria. In some embodiments, the correlation criteria comprises correlation factor, model fitness, trend analysis, constraint by physics of a subsurface region, or any combination thereof.

In some embodiments, identifying the first subset of property parameters from the set of property parameters that correlate to substantially all property parameters of the set of property parameters comprises transposing the obtained values for the plurality of samples, using a pairwise correlation matrix, or any combination thereof.

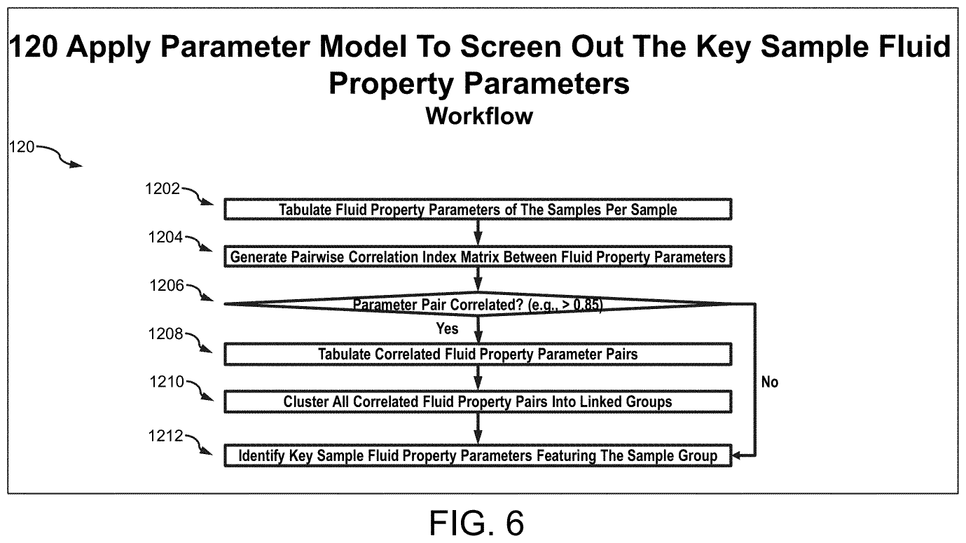

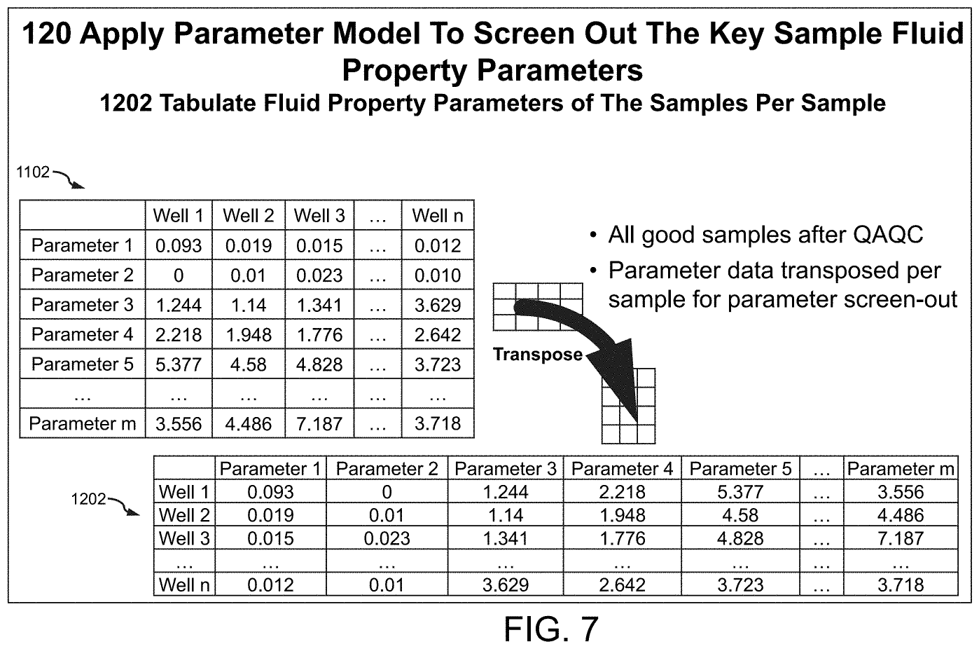

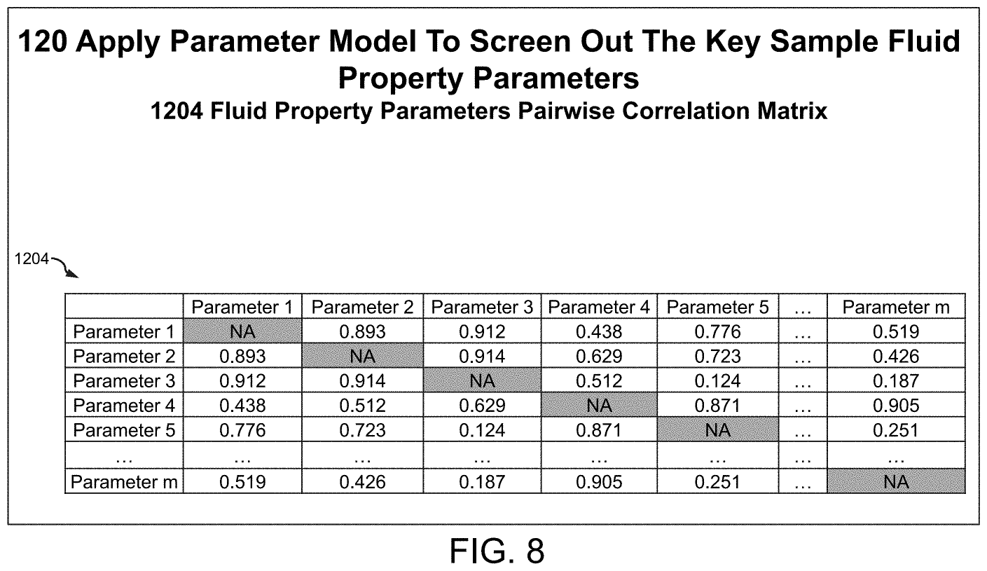

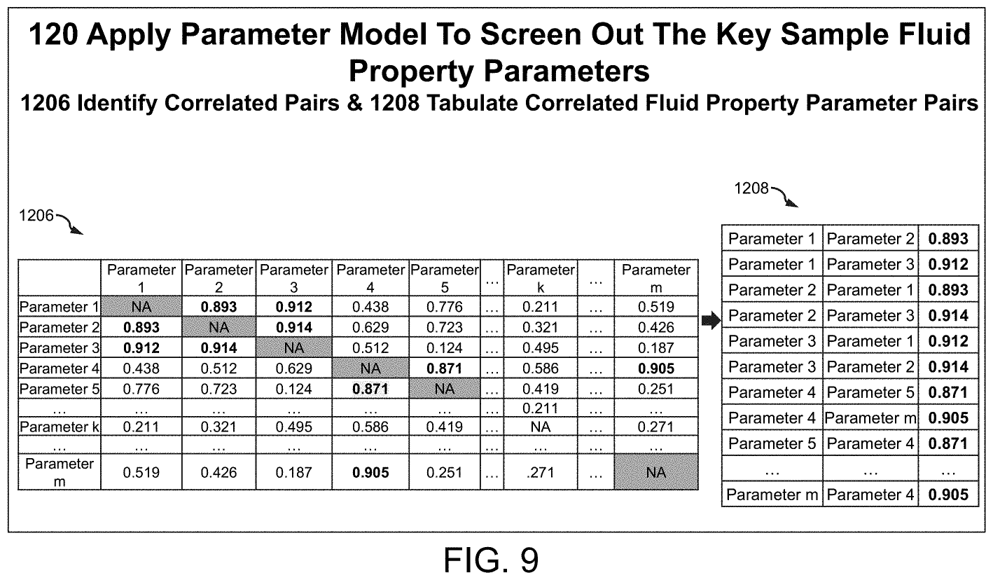

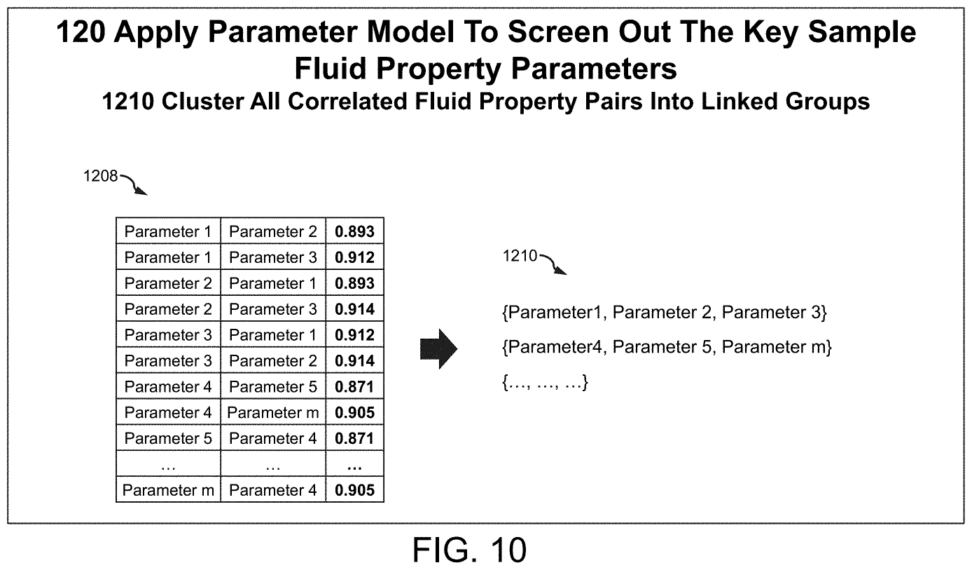

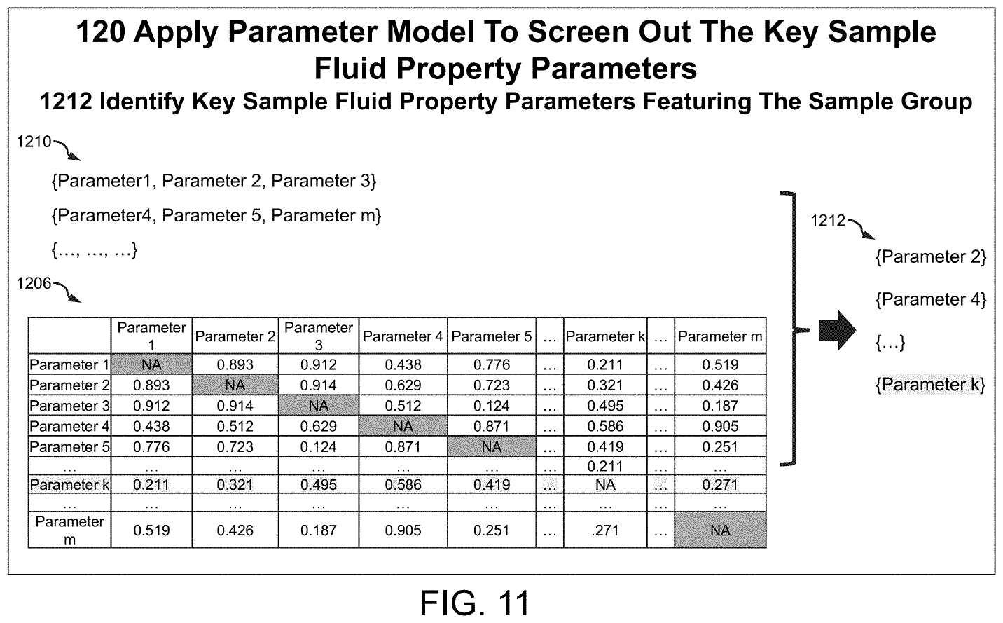

FIG. 6 illustrates one embodiment of block 120 in FIG. 1. FIG. 7 illustrates one example of block 1202 in FIG. 6. FIG. 8 illustrates one example of block 1204 in FIG. 6. FIG. 9 illustrates one example of block 1206 in FIG. 6 and one example of block 1208 in FIG. 6. FIG. 10 illustrates one example of block 1210 in FIG. 6.

The method 90 includes generating at least one model using the first subset of property parameters and a database corresponding to the at least one model, and using the at least one model for generating a value for at least one other property parameter (e.g., remaining subset or fewer than the remaining subset) of the set of property parameters (e.g., see block 130 in the figures). The first subset of property parameters and the at least one other property parameter are different.

In some embodiments, generating the at least one model using the first subset of property parameters comprises generating at least one best-fit model using the first subset of property parameters.

In some embodiments, generating the at least one model using the first subset of property parameters comprises using a machine learning algorithm to search for at least one best fit model. In some embodiments, the machine learning algorithm comprises: Genetic Algorithm (GA), Evolution Strategy (ES), Genetic Programming (GP), Biogeography Based Optimizer (BBO), Evolutionary Programming (EP), Simulated Annealing (SA), Gravitational Search Algorithm (GSA), Charged System Search (CSS), Central Force Optimization (CFO), Black Hole Algorithm (BH), Particle Swarm Optimization (PSO), Crow Search Algorithm (CSA), Dragonfly Algorithm (DA), Artificial Bee Colony (ABC), Cuckook Search (CS), Moth Swam Algorithm (MSA), Ant Colony Optimization Algorithm (ACO), Grey Wolf Optimization Algorithm (GWO), Stochastic Fractal Search (SFS), Sine Cosine Algorithm (SCA), Water Cycle Algorithm (WCA), Whale Optimization Algorithm (WOA), Bat Algorithm (BA), or any combination thereof.

In some embodiments, generating the at least one model using the first subset of property parameters comprises using a machine learning algorithm to perform regression. In some embodiments, the machine learning algorithm comprises: Ordinary Least Square Regression (OLSR), Linear Regression, Polynomial Regression, Stepwise Regression, Multivariate Adaptive Regression Splines (MARS), Random Forest, Neural Network, Gradient Boosting Machines (GBM), Gradient Boosted Regression Trees (GBRT), Locally Estimated Scatterplot Smoothing (LOESS), Jacknife Regression, Ridge Regression, Lease Absolute Shrinkage and Selection Operator (LASSO), Elastic Net, Lease-Angle Regression (LARS), Support Vector Machine (SVM), Classification and Regression Tree (CART), or any combination thereof.

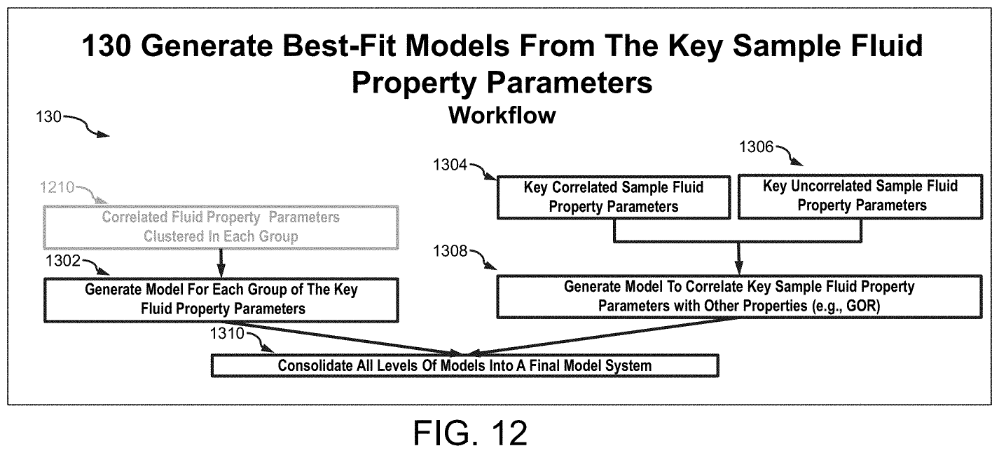

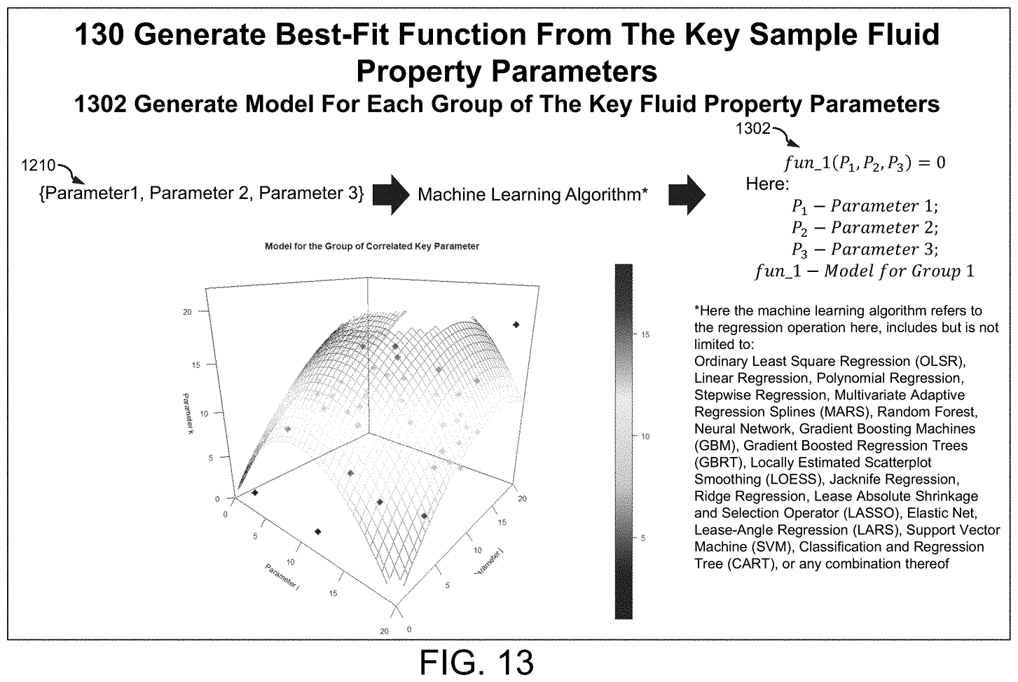

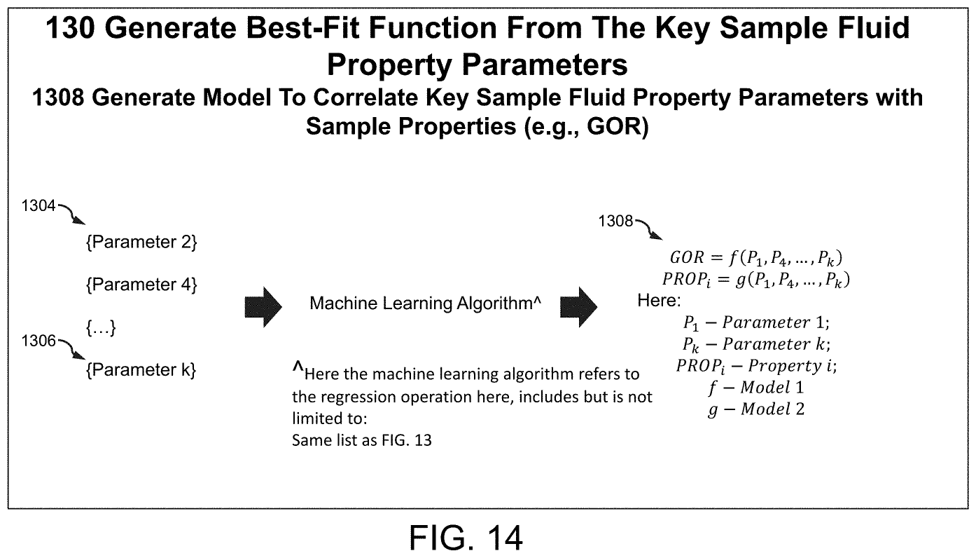

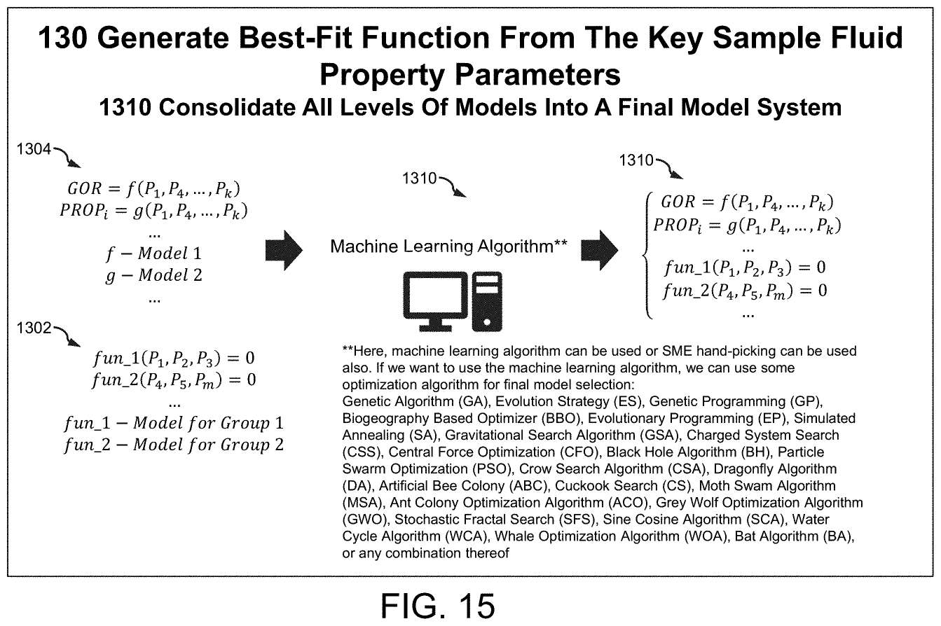

FIG. 12 illustrates one embodiment of block 130 in FIG. 1. FIG. 13 illustrates one example of block 1302 in FIG. 12. FIG. 14 illustrates one example of block 1304 in FIG. 12, block 1306 in FIG. 12, and block 1308 in FIG. 12. FIG. 15 illustrates one example of block 1310 in FIG. 12.

The method 90 includes obtaining a value for a particular parameter of the first subset of property parameters for an additional sample, and using the value for the particular parameter of the first subset of property parameters for the additional sample in the at least one model to generate a value for at least one other property for the additional sample (e.g., see blocks 140-160 in the figures). In some embodiments, a value for GOR is generated for the additional sample, a value for PVT is generated for the additional sample, a value for viscosity is generated for the additional sample, a value for composition is generated for the additional sample, or any combination thereof.

The method 90 includes comparing the generated value for the at least one other property parameter for the additional sample to a measured value for the at least one other property parameter for the additional sample, and updating the at least one model and the database corresponding to the at least one model using the measured value for the at least one other property parameter for the additional sample in response to the comparison (e.g., see blocks 170-190 in the figures). In some embodiments, the at least one model and the database corresponding to the at least one model are updated if an absolute difference between the generated value and the measured value is less than about 20%, optionally, less than 15% or less than 10% or less than 5% or in a range of 0% to 20%.

As an example, assume that the set of property parameters includes ten property parameters. A first subset of three property parameters may be identified and used to generate a value for one other property parameter from the set of property parameters. Alternatively, a first subset of three property parameters may be identified and used to generate two values for two other property parameters from the set of property parameters, and so on. Alternatively, a first subset of three property parameters may be identified and used to generate seven values for seven other property parameters from the set of property parameters for an additional sample.

Those of ordinary skill in the art will appreciate that modification may be made to the embodiments provided herein. For example, in the method 90, blocks 150 and 160 may be combined or kept separate.

As another example, at least a portion of the method 90 (e.g., a portion or entire database corresponding to the at least one model) may be utilized as input to a method 200 as illustrated in the figures. Thus, the method 90 may optionally include obtaining values for a second plurality of samples, wherein the values correspond to a second set of property parameters and wherein at least some of the obtained values for the second plurality of samples are obtained from the database corresponding to the at least one model (e.g., see block 210 in the figures); performing bi-variate modelling on the second set of property parameters to generate bi-variate relationships for the second set of property parameters and selecting the bi-variate relationships that satisfy correlation criteria (e.g., see block 230 in the figures); performing multi-variate modelling on the property parameters corresponding to the unselected bi-variate relationships to generate multi-variate relationships for the unselected bi-variate relationships and selecting the multi-variate relationships that satisfy the correlation criteria (e.g., see block 240 in the figures); and combining the bi-variate models corresponding to the selected bi-variate relationships and the multi-variate models corresponding to the selected multi-variate relationships to generate a combined model comprising the corresponding parameters (e.g., see block 250 in the figures). In some embodiments, the obtained values for the second plurality of samples and the second set of property parameters are substantially the same as those in claim 1 (e.g., the method 90 such as the database). Substantially the same refers to all are the same in one embodiment. Substantially the same refers to 90% to 100% being the same in another embodiment. Substantially the same refers to 80% to 100% being the same in another embodiment. Substantially the same refers to 70% to 100% being the same in another embodiment. Substantially the same refers to 60% to 100% being the same in another embodiment. Substantially the same refers to 51% to 100% being the same in another embodiment.

A person of ordinary skill the art will therefore understand that the method 90 may be performed in isolation, the method 200 may be performed in isolation, or both the method 90 and the method 200 may be performed (e.g., the method 90 may be performed before the method 200 and at least a portion of the method 90 may serve as input to the method 200). As such, block 210 of the method 200 can use solely input from the method 90 in one embodiment, the method 200 can use solely input from some other method(s) in another embodiment, or the method 200 can use input from both the method 90 and some other method(s) in another embodiment.

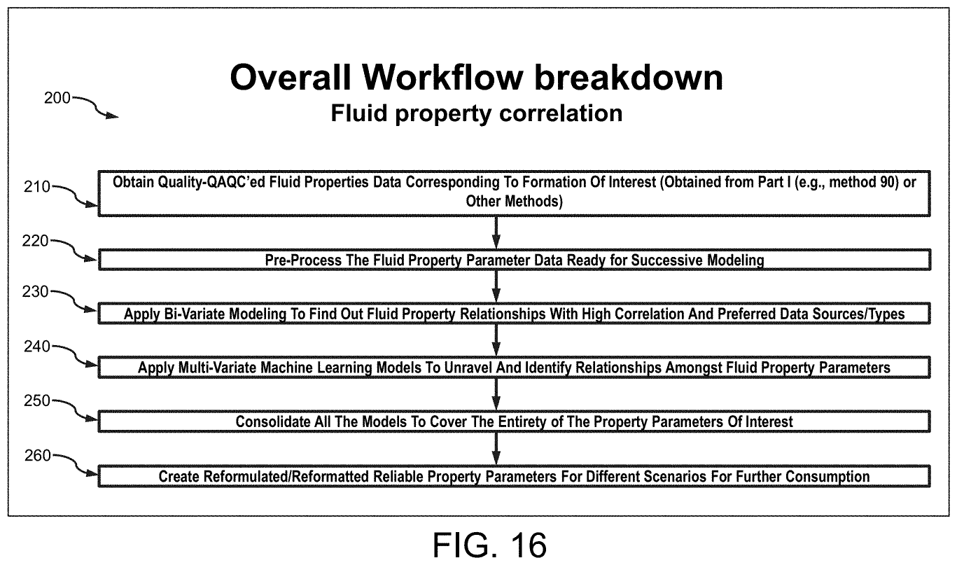

One embodiment of a method of generating values for property parameters is provided in the accompanying figures as a method 200. Although fluid samples, unconventional reservoirs, hydraulic fracturing, and the like are mentioned herein, the claims are not limited to these. The method 200 may be executed by a system, such as computing system (e.g., at least one computer) as illustrated in FIGS. 40A-40B. FIG. 16 illustrates one embodiment of the method 200.

The method 200 includes obtaining values for a plurality of samples, wherein the values correspond to a set of property parameters (e.g., see block 210 in the figures). For example, this may include obtaining (e.g., receiving, accessing, requesting, etc.) Quality-QAQC′ed fluid properties data. As explained hereinabove, block 210 of the method 200 can use solely input from the method 90 in one embodiment, the method 200 can use solely input from some other method(s) in another embodiment, or the method 200 can use input from both the method 90 and some other method(s) in another embodiment. Examples of property parameters include, but are not limited to, composition, gas oil ratio (GOR), condensate gas ratio (CGR), water oil ratio (WOR), water gas ratio (WGR), density, viscosity, compressibility, Young modulus, geochemical characterization, or any combination thereof.

In some embodiments, the values are obtained for a plurality of fluid samples, and wherein the values correspond to a set of fluid property parameters. In some embodiments, the plurality of fluid samples comprises an oil sample from a separator, a gas sample from a separator, or any combination thereof. The term “fluid” refers to liquid and gaseous phases.

In some embodiments, the values are obtained for a plurality of fluid samples and solid samples, and wherein the values correspond to a set of fluid and solid property parameters. In some embodiments, the plurality of fluid samples and solid samples comprises an oil sample from a separator, a gas sample from a separator, or any combination thereof. A solid sample may be a core sample, a rock sample, or practically any other solid sample in the hydrocarbon industry such as a solid sample from heavy oil.

In some embodiments, the values are obtained for a plurality of solid samples, and wherein the values correspond to a set of solid property parameters.

In some embodiments, at least a portion of the obtained values for the plurality of samples satisfy quality criteria. In some embodiments, the quality criteria comprises measurement error, first principles, constraint by physics of a subsurface region, acquisition of the plurality of samples, thermodynamic consistency of the plurality of samples, quantity of the plurality of samples, or any combination thereof (e.g., see block 210 in the figures). Acquisition of the plurality of samples may include timing of the acquisition, acquisition procedure/acquisition methodology, acquisition conditions, etc.

Optionally, the method 200 includes pre-processing at least a portion of the obtained values for a plurality of samples before performing the bi-variate modelling (e.g., see block 220 in the figures). The pre-processing comprises labelling, transforming using a transformation algorithm, or any combination thereof. In some embodiments, the transformation algorithm comprises reciprocal, logarithmic, exponential, power-law, ratio, absolute value, trigonometric, dimensionless, sigmoid, or any combination thereof. In some embodiments, a combination of the pre-processed data and the obtained values may be used in performing the bi-variate modelling.

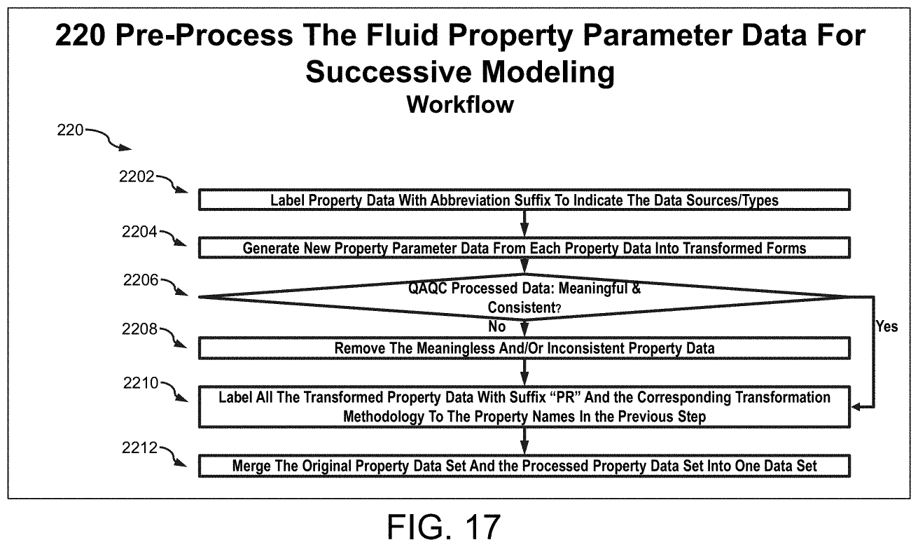

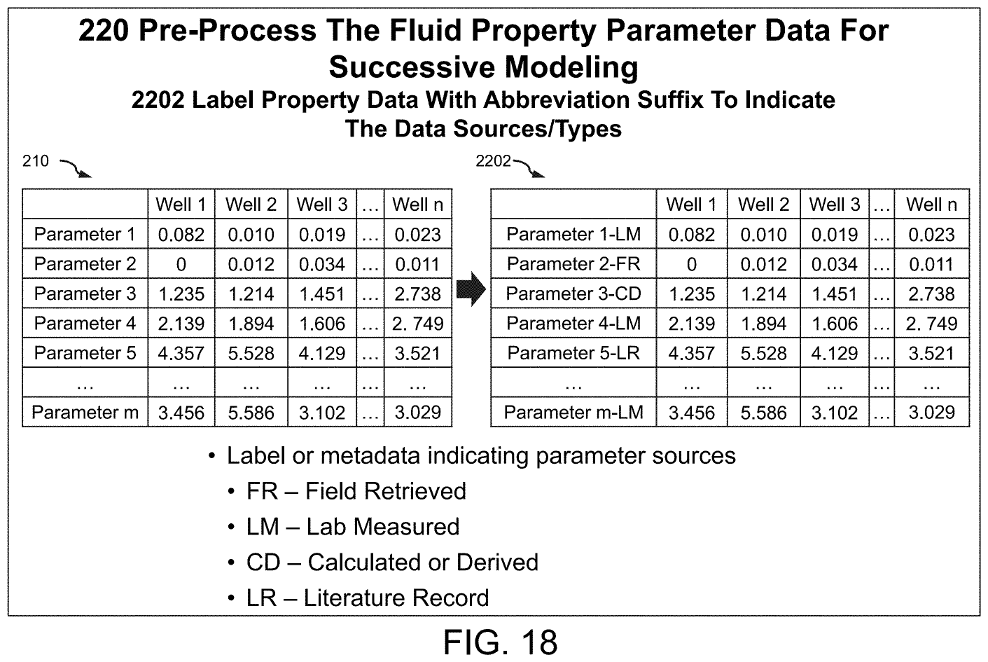

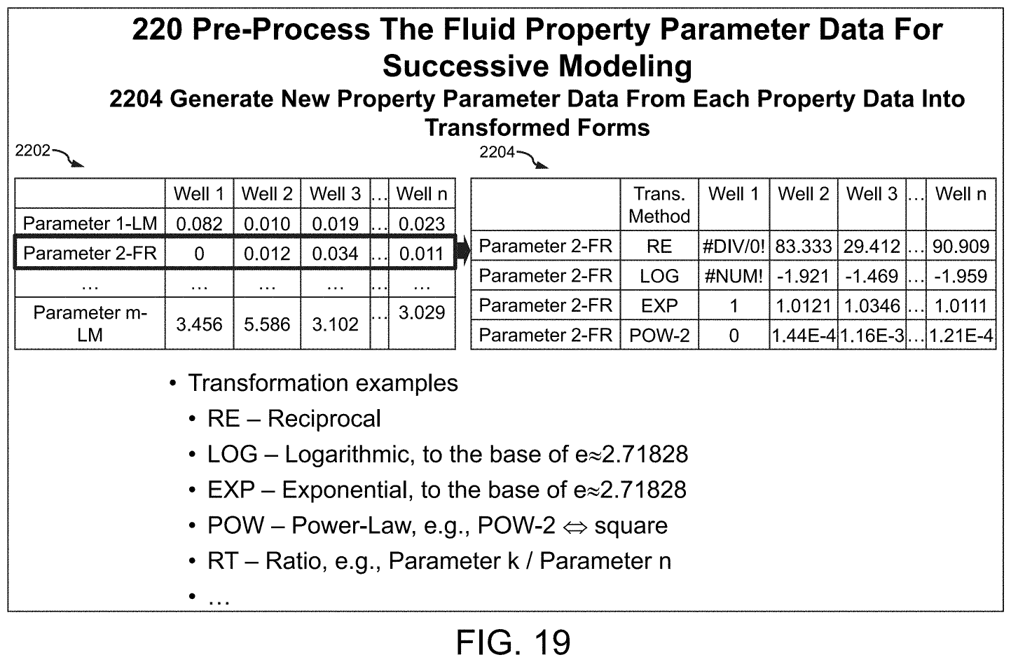

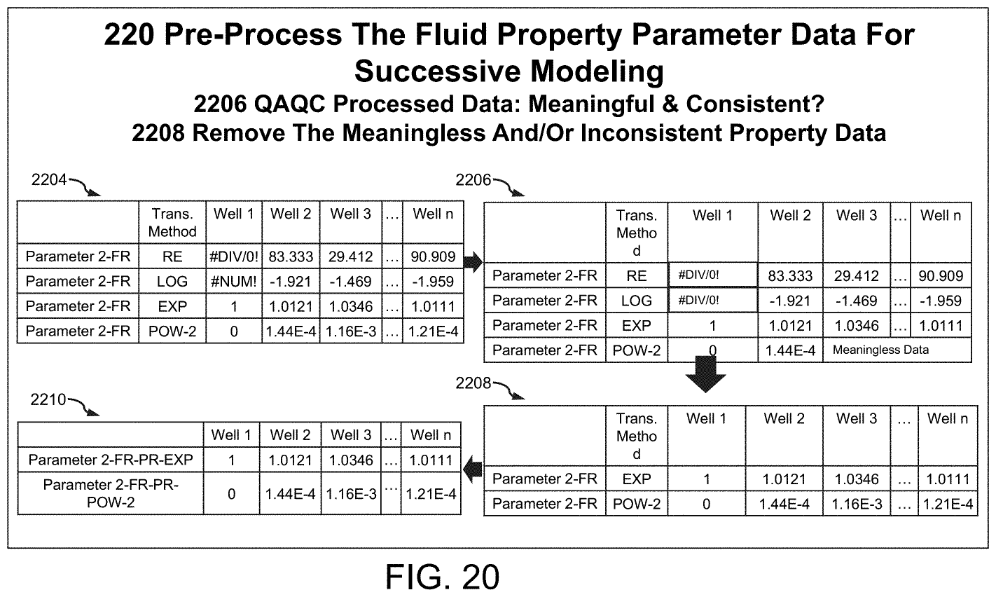

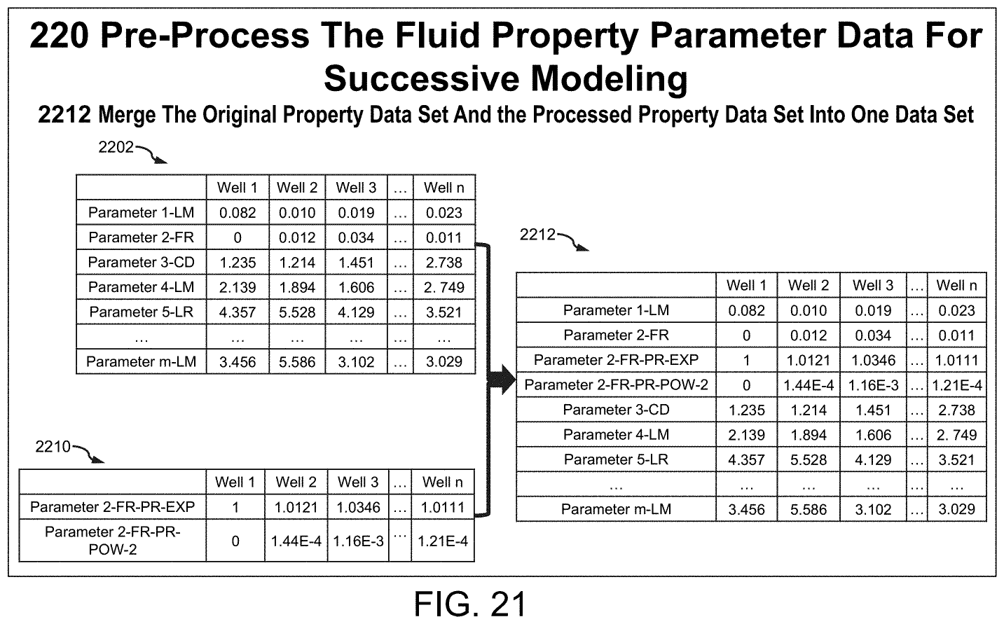

FIG. 17 illustrates one embodiment of block 220 in FIG. 16. FIG. 18 illustrates one example of block 2202 in FIG. 17. FIG. 19 illustrates one example of block 2204 in FIG. 17. FIG. 20 illustrates one example of block 2206 in FIG. 17, block 2208 in FIG. 17, and block 2210 in FIG. 17. FIG. 21 illustrates one example of block 2212 in FIG. 17.

The method 200 includes performing bi-variate modelling on the set of property parameters to generate bi-variate relationships for the set of property parameters and selecting the bi-variate relationships that satisfy correlation criteria (e.g., see block 230 in the figures).

In some embodiments, performing the bi-variate modelling on the set of property parameters to generate the bi-variate relationships for the set of property parameters and selecting the bi-variate relationships that satisfy correlation criteria comprises using a machine learning algorithm for generating the bi-variate relationships. In some embodiments, the machine learning algorithm comprises Ordinary Least Square Regression (OLSR), Linear Regression, Polynomial Regression, Stepwise Regression, Locally Estimated Scatterplot Smoothing (LOESS), Jacknife Regression, Ridge Regression, Lease Absolute Shrinkage and Selection Operator (LASSO), Elastic Net, Lease-Angle Regression (LARS), Support Vector Machine (SVM), or any combination thereof.

In some embodiments, performing the bi-variate modelling on the set of property parameters to generate the bi-variate relationships for the set of property parameters and selecting the bi-variate relationships that satisfy correlation criteria comprises using a machine learning algorithm for selecting the bi-variate relationships. In some embodiments, the machine learning algorithm comprises Genetic Algorithm (GA), Evolution Strategy (ES), Genetic Programming (GP), Biogeography Based Optimizer (BBO), Evolutionary Programming (EP), Simulated Annealing (SA), Gravitational Search Algorithm (GSA), Charged System Search (CSS), Central Force Optimization (CFO), Black Hole Algorithm (BH), Particle Swarm Optimization (PSO), Crow Search Algorithm (CSA), Dragonfly Algorithm (DA), Artificial Bee Colony (ABC), Cuckook Search (CS), Moth Swam Algorithm (MSA), Ant Colony Optimization Algorithm (ACO), Grey Wolf Optimization Algorithm (GWO), Stochastic Fractal Search (SFS), Sine Cosine Algorithm (SCA), Water Cycle Algorithm (WCA), Whale Optimization Algorithm (WOA), Bat Algorithm (BA), lease-Square Algorithm, Gradient Descent Algorithm, Downhill Simplex Algorithm, Levenberg-Marquardt algorithm, or any combination thereof.

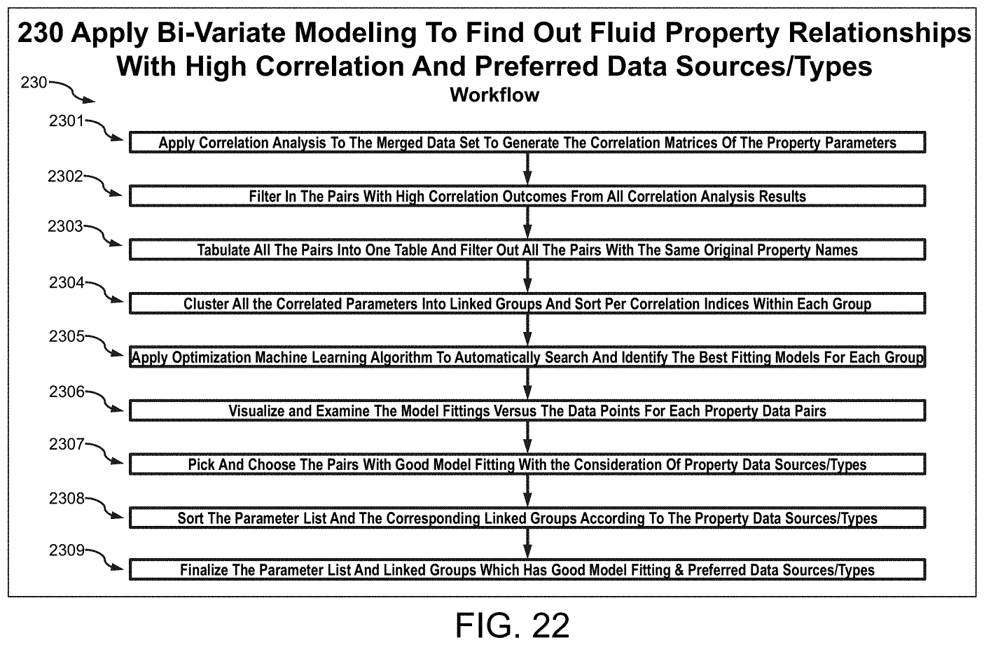

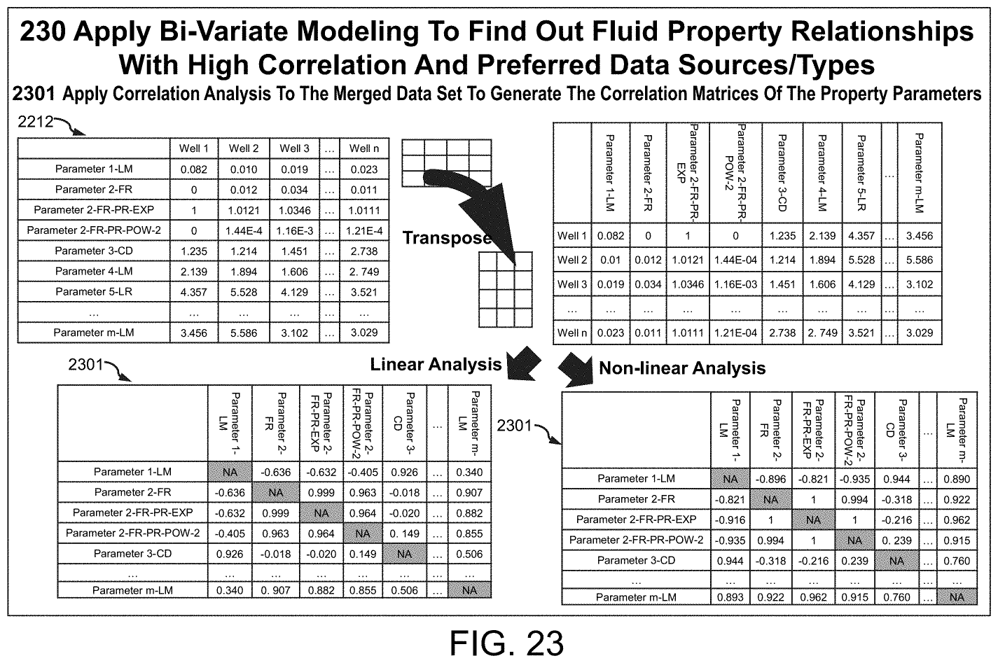

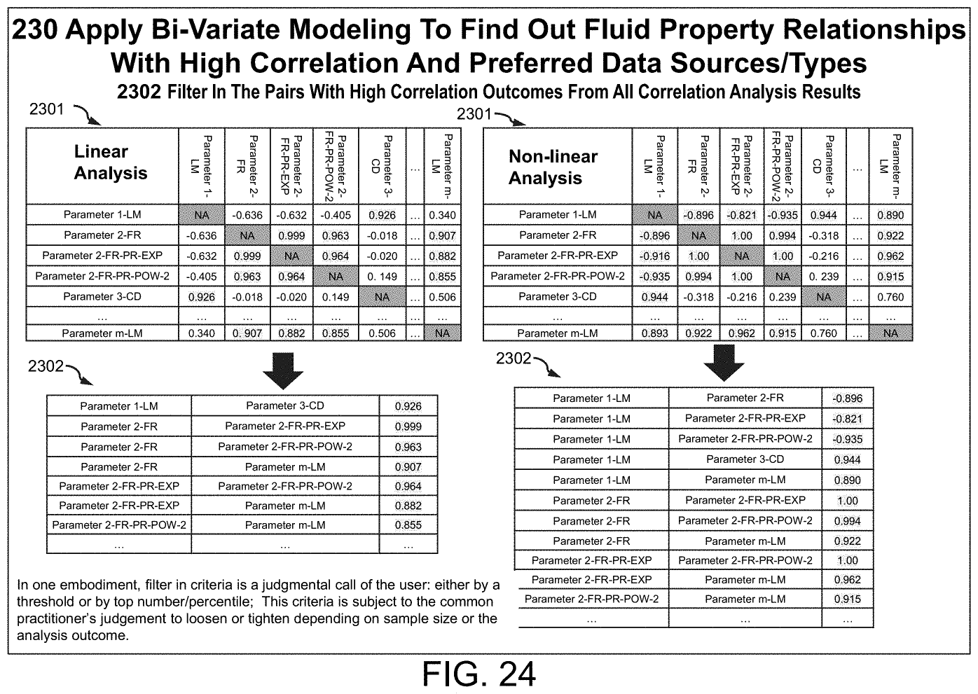

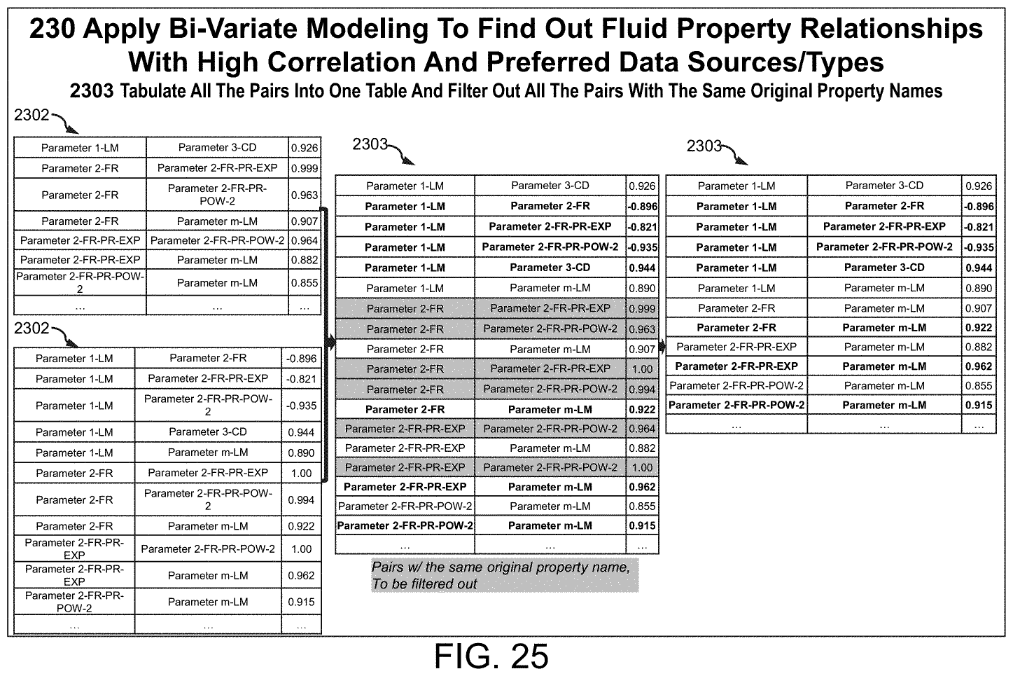

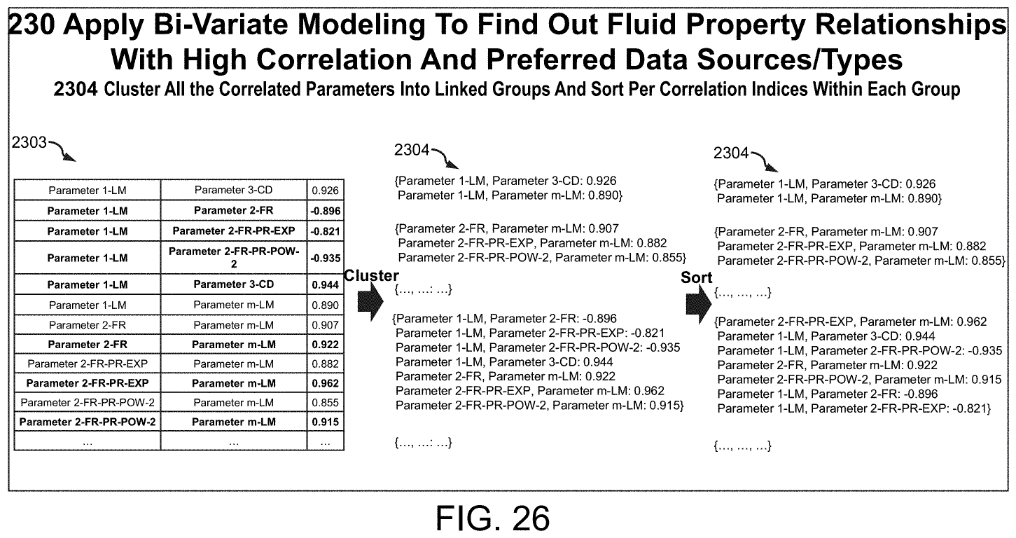

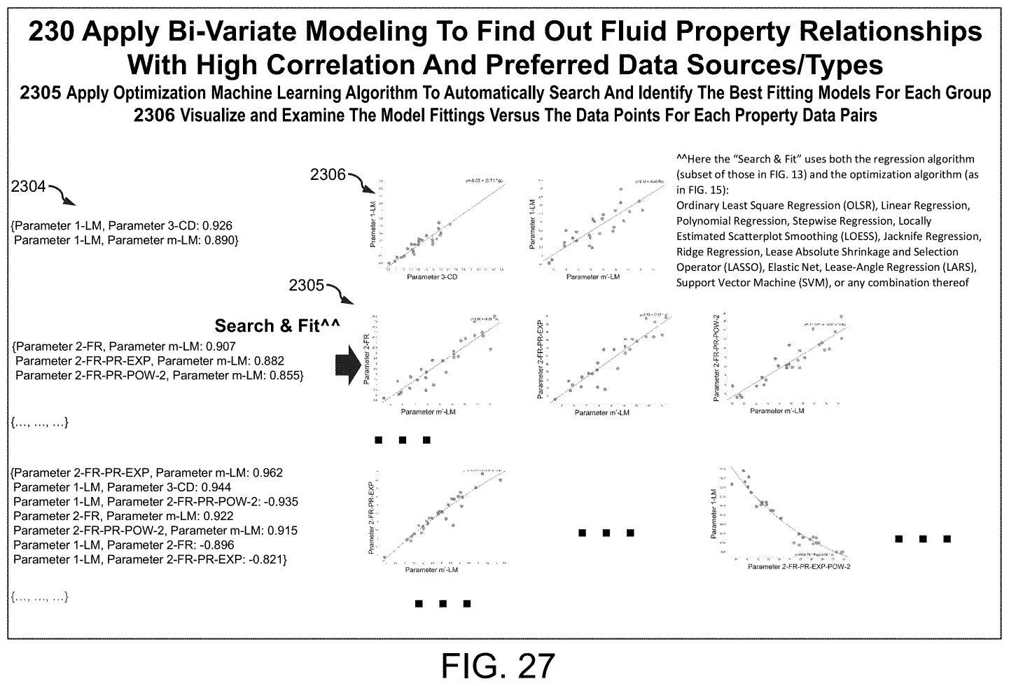

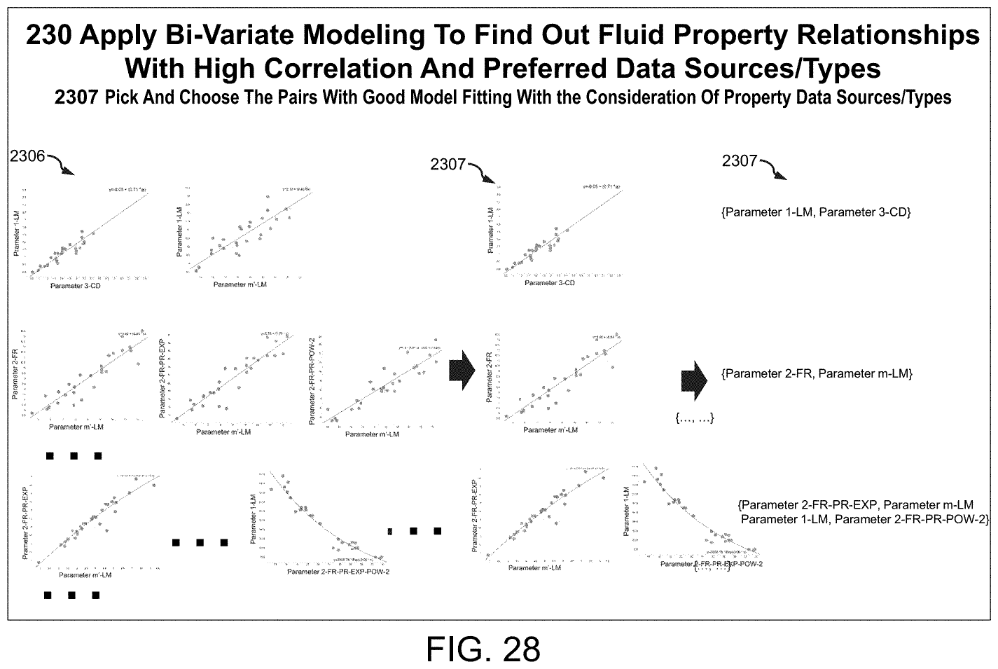

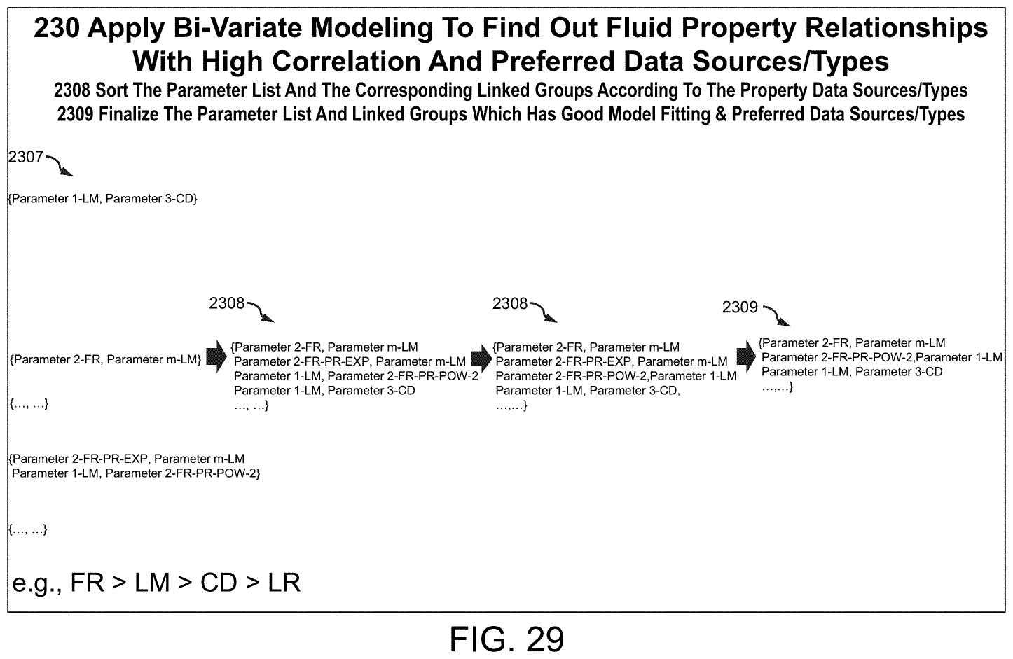

FIG. 22 illustrates one embodiment of block 230 in FIG. 16. FIG. 23 illustrates one example of block 2301 in FIG. 22. FIG. 24 illustrates one example of block 2302 in FIG. 22. FIG. 25 illustrates one example of block 2303 in FIG. 22. FIG. 26 illustrates one example of block 2304 in FIG. 22. FIG. 27 illustrates one example of block 2305 in FIG. 22 and block 2306 in FIG. 22. FIG. 28 illustrates one example of block 2307 in FIG. 22. FIG. 29 illustrates one example of block 2308 in FIG. 22 and block 2309 in FIG. 22.

The method 200 includes performing multi-variate modelling on the property parameters corresponding to the unselected bi-variate relationships to generate multi-variate relationships for the unselected bi-variate relationships and selecting the multi-variate relationships that satisfy the correlation criteria (e.g., see block 240 in the figures).

In some embodiments, performing the multi-variate modelling further comprises performing the multi-variate modelling on the property parameters corresponding to the selected bi-variate relationships in addition to the unselected bi-variate relationships.

In some embodiments, performing the multi-variate modelling on the property parameters corresponding to the unselected bi-variate relationships to generate the multi-variate relationships for the unselected bi-variate relationships and selecting the multi-variate relationships that satisfy the correlation criteria comprises using a machine learning algorithm for generating the multi-variate relationships. In some embodiments, the machine learning algorithm comprises Ordinary Least Square Regression (OLSR), Linear Regression, Polynomial Regression, Stepwise Regression, Multivariate Adaptive Regression Splines (MARS), Random Forest, Neural Network, Gradient Boosting Machines (GBM), Gradient Boosted Regression Trees (GBRT), Locally Estimated Scatterplot Smoothing (LOESS), Jacknife Regression, Ridge Regression, Lease Absolute Shrinkage and Selection Operator (LASSO), Elastic Net, Lease-Angle Regression (LARS), Support Vector Machine (SVM), Classification and Regression Tree (CART), or any combination thereof.

In some embodiments, performing multi-variate modelling on the property parameters corresponding to the unselected bi-variate relationships to generate the multi-variate relationships for the unselected bi-variate relationships and selecting the multi-variate relationships that satisfy the correlation criteria comprises using a machine learning algorithm for selecting the multi-variate relationships. In some embodiments, the machine learning algorithm comprising Genetic Algorithm (GA), Evolution Strategy (ES), Genetic Programming (GP), Biogeography Based Optimizer (BBO), Evolutionary Programming (EP), Simulated Annealing (SA), Gravitational Search Algorithm (GSA), Charged System Search (CSS), Central Force Optimization (CFO), Black Hole Algorithm (BH), Particle Swarm Optimization (PSO), Crow Search Algorithm (CSA), Dragonfly Algorithm (DA), Artificial Bee Colony (ABC), Cuckook Search (CS), Moth Swam Algorithm (MSA), Ant Colony Optimization Algorithm (ACO), Grey Wolf Optimization Algorithm (GWO), Stochastic Fractal Search (SFS), Sine Cosine Algorithm (SCA), Water Cycle Algorithm (WCA), Whale Optimization Algorithm (WOA), Bat Algorithm (BA), lease-Square Algorithm, Gradient Descent Algorithm, Downhill Simplex Algorithm, Levenberg-Marquardt algorithm, or any combination thereof.

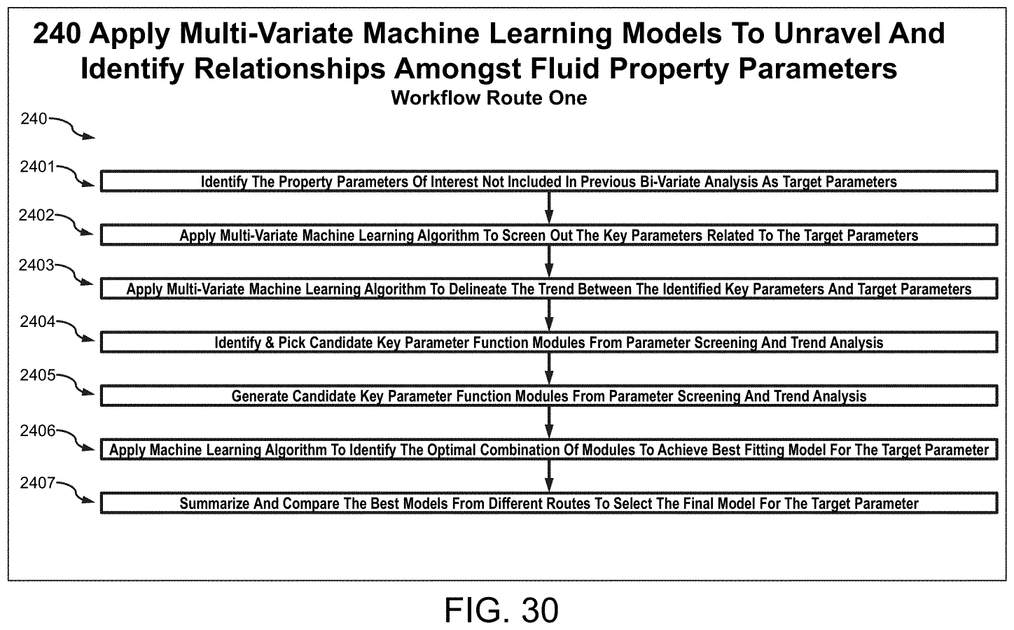

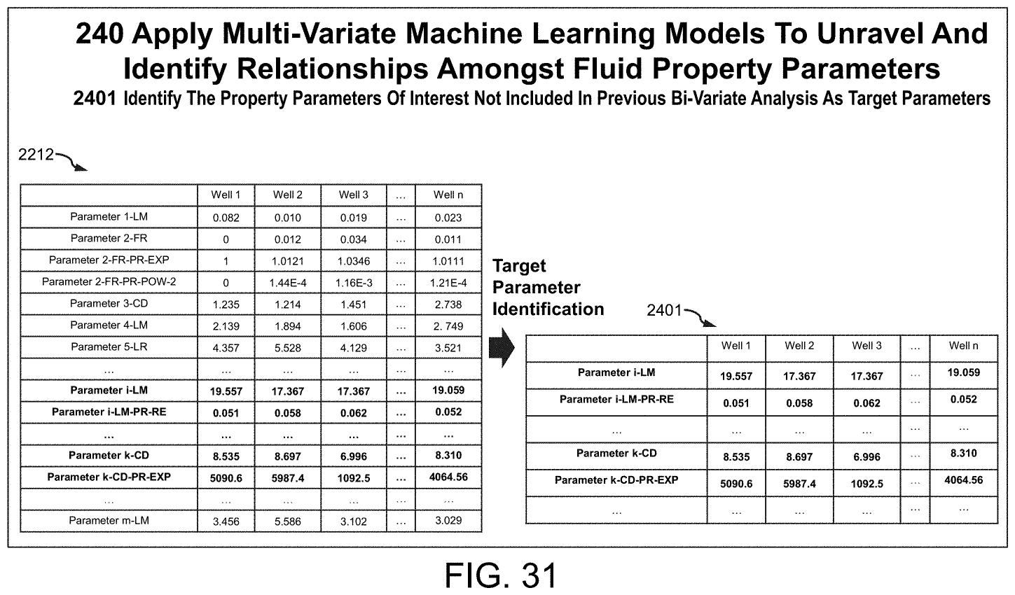

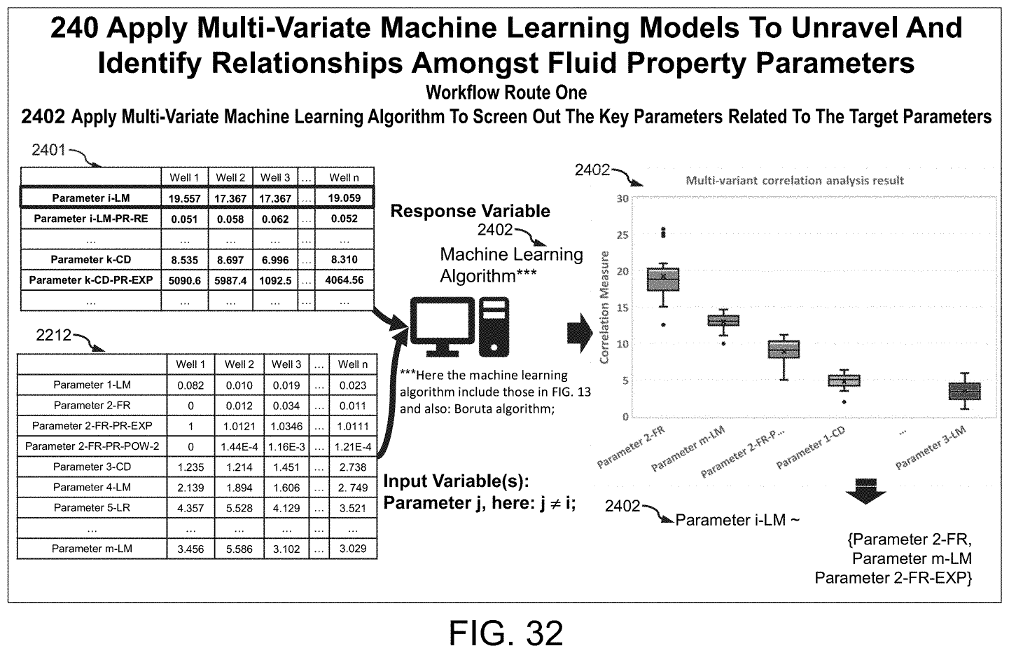

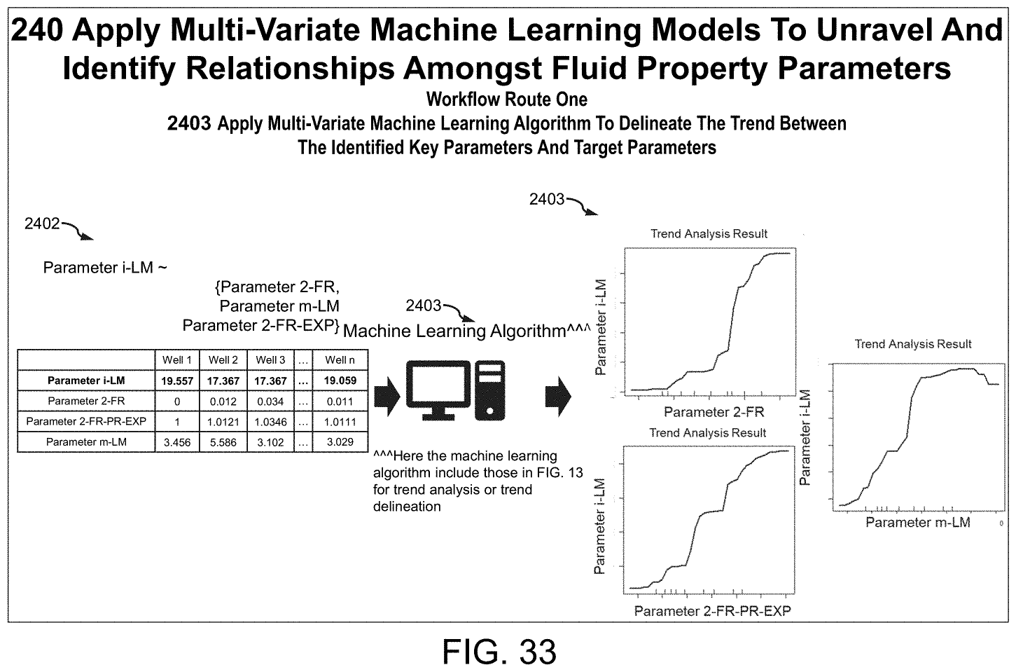

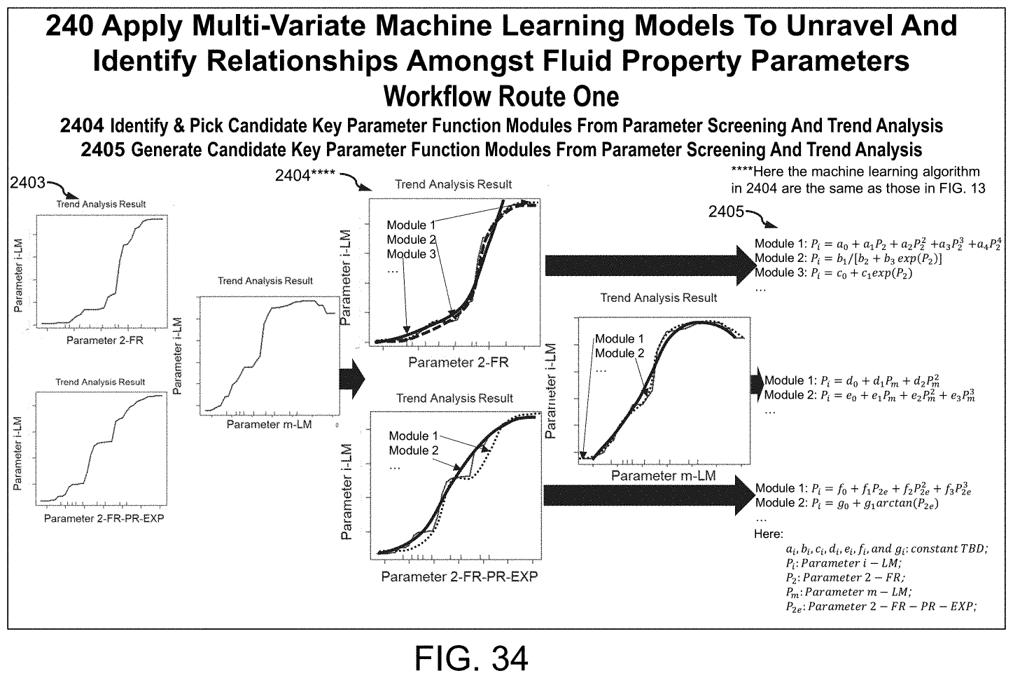

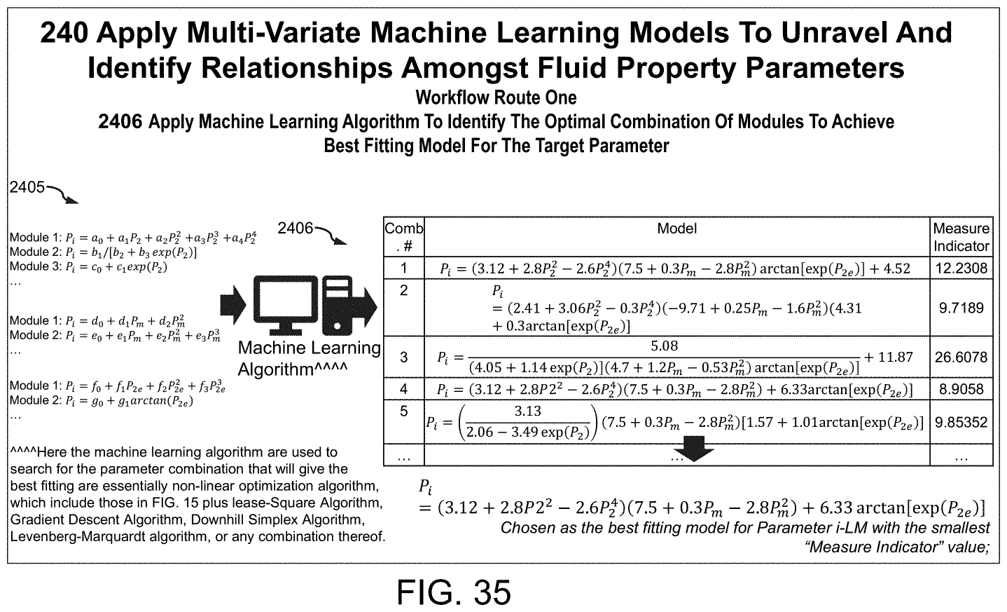

FIG. 30 illustrates one embodiment of block 240 in FIG. 16. FIG. 31 illustrates one example of block 2401 in FIG. 30. FIG. 32 illustrates one example of block 2402 in FIG. 30. FIG. 33 illustrates one example of block 2403 in FIG. 30. FIG. 33 illustrates one example of block 2403 in FIG. 30. FIG. 34 illustrates one example of block 2404 in FIG. 30 and block 2405 in FIG. 30. FIG. 35 illustrates one example of block 2406 in FIG. 30.

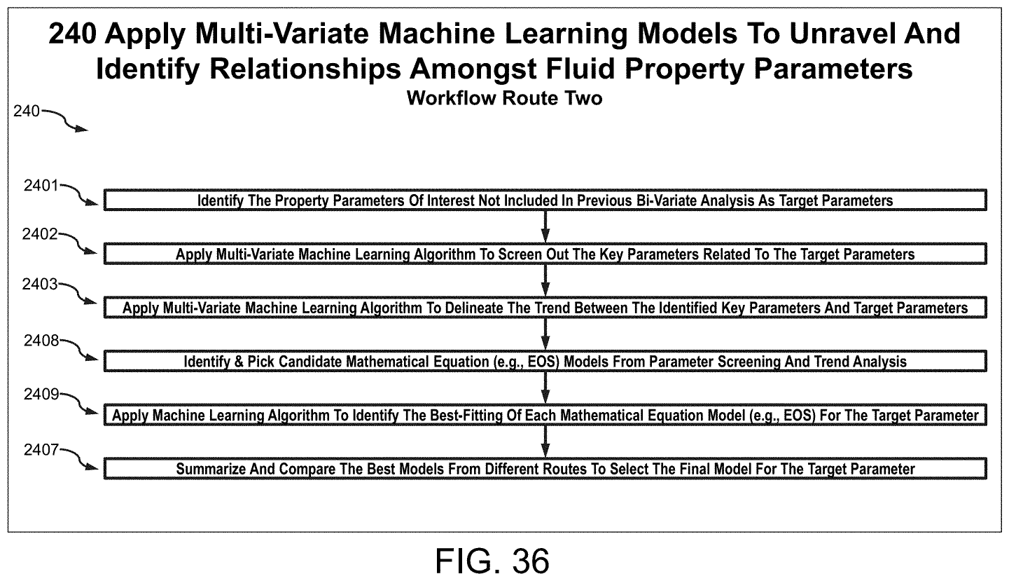

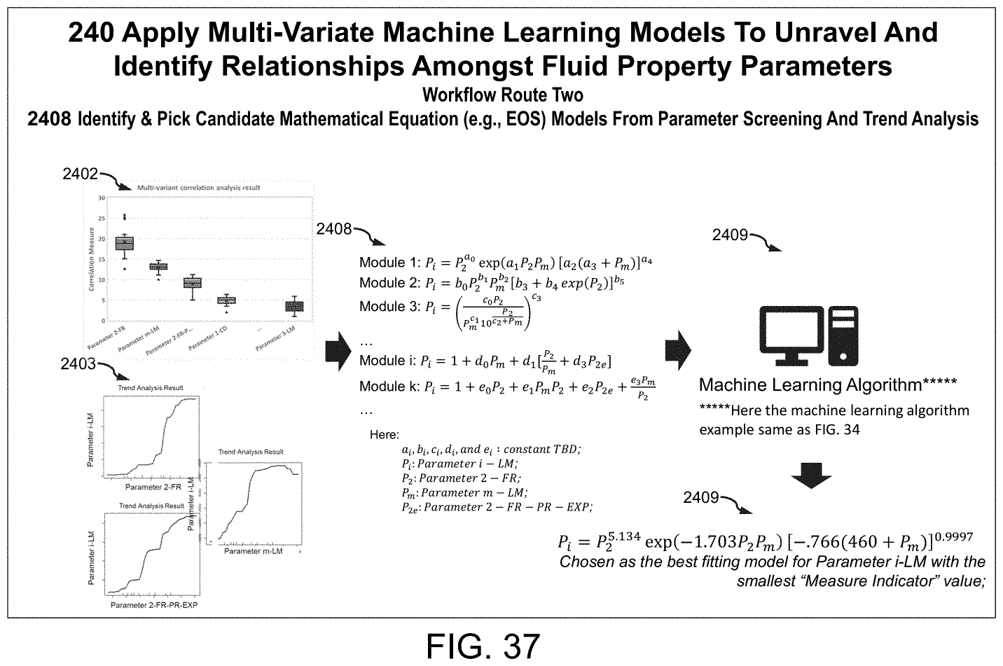

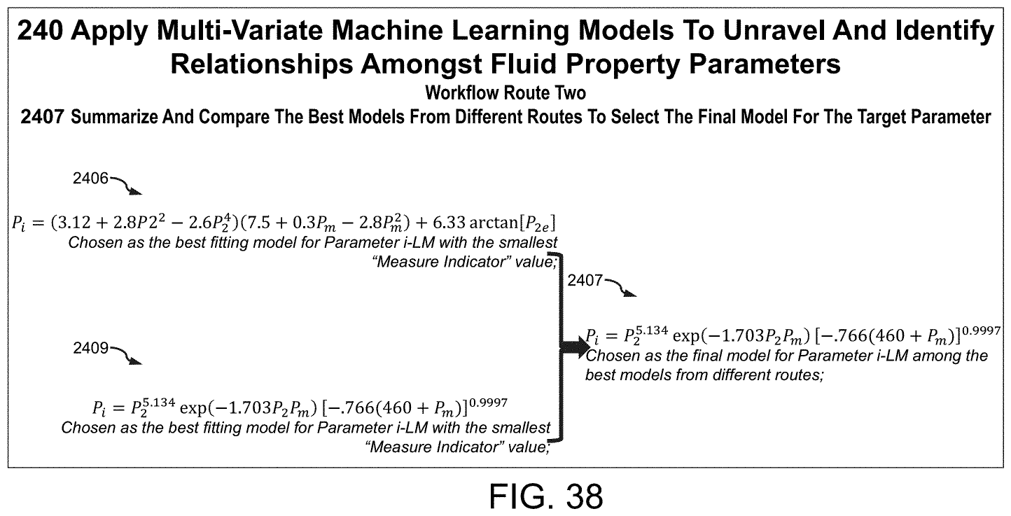

FIG. 36 illustrates a second embodiment of block 240 in FIG. 16. FIG. 37 illustrates one example of block 2408 in FIG. 36 and block 2409 in FIG. 36. FIG. 38 illustrates one example of block 2407 in FIG. 36.

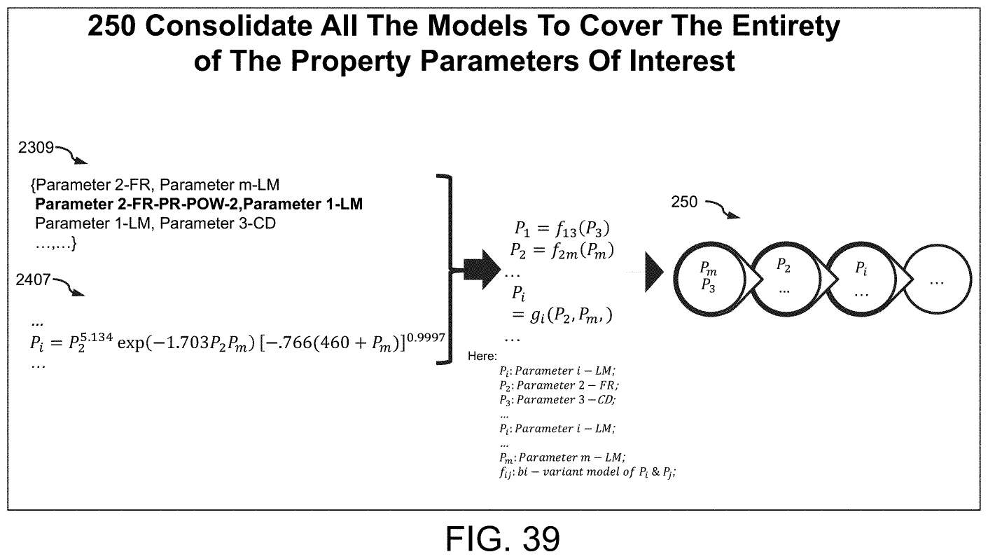

The method 200 includes combining the bi-variate models corresponding to the selected bi-variate relationships and the multi-variate models corresponding to the selected multi-variate relationships to generate a combined model comprising the corresponding parameters (e.g., see block 250 in the figures). FIG. 39 illustrates one embodiment of block 250 in FIG. 16.

The method 200 includes obtaining a value for a particular parameter of the combined model for an additional sample; and using the value of the particular parameter for the additional sample in the combined model to generate a value for at least one other property parameter for the additional sample (e.g., see block 260 in the figures).

The method 200 includes modifying the generated value into a format that is consumable by a simulator, a calculator, a particular application, or any combination thereof (e.g., see block 260 in the figures). In some embodiments, the simulator comprises a reservoir simulator, a production simulator, a process simulator, or any combination thereof. In some embodiments, the calculator comprises a pipeline calculator, reactor calculator, refinery calculator, or any combination thereof. In some embodiment, the particular application comprises a economic application, reserve/booking application, or any combination thereof.

In some embodiments, the method 200 includes modifying the generated value; and modifying the generated value comprises changing the generated value to be a function of pressure, a function of temperature, a function of composition, a function of state, a function of volume, or any combination thereof (e.g., see block 260 in the figures).

In some embodiments, the method 200 includes modifying the generated value; and modifying the generated value comprises calculating a slope (e.g., see block 260 in the figures). In some embodiments, the calculated slope is used as an input to a simulator.

Thus, the generated value may be modified. For example, to consume fluid property parameters of interest, a particular format/syntax of the parameters may be needed. Examples are fluid property information as a function of pressure and temperature for usage in reservoir and production simulation applications. The combined model (from block 250) is considered a vehicle through which parameters of interest may be re-calculated and represented with a target format.

Those of ordinary skill in the art will appreciate that modification may be made to the embodiments provided herein. For example, the method 200 may include a pre-processing portion in some embodiments, but not other embodiments. As explained hereinabove, block 210 of the method 200 can use solely input from the method 90 in one embodiment, the method 200 can use solely input from some other method(s) in another embodiment, or the method 200 can use input from both the method 90 and some other method(s) in another embodiment.

Example 1: A large database was developed to establish fluid property relation as a function of minimum fluid property input such as pressure, temperature, API gravity, gas gravity, and gas oil ratio (GOR). The developed correlations were used to estimate fluid properties of few samples collected at a later stage of fluid model development. In the example, formation volume factor of the some of the collected samples were predicted prior of actual PVT testing. In the evaluation cases, estimated Oil FVF (formation volume factor) was within 2% of the final measured laboratory value which is well within the expected error of measurement.

Example 2: A robust and proper workflow was established for fluid sampling, analysis, and characterization in unconventional light oil and gas condensate systems, ranging from vendor selection, field sample timing and procedures, initial gas oil ratio evaluation, types of laboratory tests, QC (quality control, and development of optimized equation of state. Such workflow can be used for unconventional light oil and gas condensate systems.

Moreover, a quality controlled PVT database was established for a region of interest. Fluid properties from such a database have shown correlations with low standard deviations, regardless of formations and well locations. Additional 26 sets of fluid property data from volatile or light oil systems in another region of interest were further gathered from different formations and locations and merged with the data (14 sets). Fluid property data still show correlations with low standard deviation for the extended fluid property database.

Moreover, bi-variate data analysis was executed to reveal the correlations between the fluid properties. Linear and non-linear correlation studies were executed to demonstrate the pair-wise correlations between fluid properties from data points. This would reveal the pairs of properties between which there are clear and obvious trends. The result effectively clustered the properties into groups of high correlation.

Moreover, multi-variate holistic models were constructed with advanced machine learning algorithms to further unravel the underlying relationships amongst all fluid properties. For a given fluid property, the model could identify a group of candidate properties that showed statistically high correlation. The advantage of the multi-variate approach to that of bi-variate one is its high-dimensional search space which took any interactive effects into consideration. On top of the property selection, the model could generate the trend plots between the target fluid property and another related property while taking other properties' influence into consideration. The result could clearly depict the true trend or relationship in the complicated system. The relationships between the target fluid properties, such as initial saturation pressure, formation volume factor and viscosity, and some parameters such as initial gas oil ratio, reservoir temperature and pressure, can be obtained with high confidence, once the data set went through the aforementioned multi-variate analysis process.

The methods and systems of the present disclosure may, in part, use one or more models that are machine-learning algorithms. These models may be supervised or unsupervised. Supervised learning algorithms are trained using labeled data (i.e., training data) which consist of input and output pairs. By way of example and not limitation, supervised learning algorithms may include classification and/or regression algorithms such as neural networks, generative adversarial networks, linear regression, etc. Unsupervised learning algorithms are trained using unlabeled data, meaning that training data pairs are not needed. By way of example and not limitation, unsupervised learning algorithms may include clustering and/or association algorithms such as k-means clustering, principal component analysis, singular value decomposition, etc. Although the present disclosure may name specific models, those of skill in the art will appreciate that any model that may accomplish the goal may be used.

The methods and systems of the present disclosure may be implemented by a system and/or in a system, such as a system 4010 shown in FIGS. 40A-40B. The system 4010 may include one or more of a processor 4011, an interface 4012 (e.g., bus, wireless interface), an electronic storage 4013, a graphical display 4012, and/or other components. The processor 4011 may execute methods of generating values for property parameters such as, but not limited to, the method 90 and/or the method 200 discussed herein.

The electronic storage 4013 may be configured to include electronic storage medium that electronically stores information. The electronic storage 4013 may store software algorithms, information determined by the processor 4011, information received remotely, and/or other information that enables the system 4010 to function properly. For example, the electronic storage 4013 may store information relating to a database, values for a plurality of samples, and/or other information. The electronic storage media of the electronic storage 4013 may be provided integrally (i.e., substantially non-removable) with one or more components of the system 10 and/or as removable storage that is connectable to one or more components of the system 4010 via, for example, a port (e.g., a USB port, a Firewire port, etc.) or a drive (e.g., a disk drive, etc.). The electronic storage 4013 may include one or more of optically readable storage media (e.g., optical disks, etc.), magnetically readable storage media (e.g., magnetic tape, magnetic hard drive, floppy drive, etc.), electrical charge-based storage media (e.g., EPROM, EEPROM, RAM, etc.), solid-state storage media (e.g., flash drive, etc.), and/or other electronically readable storage media. The electronic storage 4013 may be a separate component within the system 4010, or the electronic storage 4013 may be provided integrally with one or more other components of the system 4010 (e.g., the processor 4011). Although the electronic storage 4013 is shown in FIGS. 40A-40B as a single entity, this is for illustrative purposes only. In some implementations, the electronic storage 4013 may comprise a plurality of storage units. These storage units may be physically located within the same device, or the electronic storage 4013 may represent storage functionality of a plurality of devices operating in coordination.

The graphical display 4014 may refer to an electronic device that provides visual presentation of information. The graphical display 4014 may include a color display and/or a non-color display. The graphical display 4014 may be configured to visually present information. The graphical display 4014 may present information using/within one or more graphical user interfaces. For example, the graphical display 4014 may present information relating to the database, a value for at least one other property for the additional sample, and/or other information.

The processor 4011 may be configured to provide information processing capabilities in the system 4010. As such, the processor 4011 may comprise one or more of a digital processor, an analog processor, a digital circuit designed to process information, a central processing unit, a graphics processing unit, a microcontroller, an analog circuit designed to process information, a state machine, and/or other mechanisms for electronically processing information. The processor 4011 may be configured to execute one or more machine-readable instructions 40100 to facilitate the method 90. The machine-readable instructions 40100 may include one or more computer program components. The machine-readable instructions 40100 may include an obtaining component 40102, an identifying component 40104, a generating component 40106, an additional sample component 40108, a comparing component 40110, a variable modelling component 40112, and/or other computer program components.

It should be appreciated that although computer program components are illustrated in FIGS. 40A-40B as being co-located within a single processing unit, one or more of computer program components may be located remotely from the other computer program components. While computer program components are described as performing or being configured to perform operations, computer program components may comprise instructions which may program processor 4011 and/or system 4010 to perform the operation.

While computer program components are described herein as being implemented via processor 4011 through machine-readable instructions 40100, this is merely for ease of reference and is not meant to be limiting. In some implementations, one or more functions of computer program components described herein may be implemented via hardware (e.g., dedicated chip, field-programmable gate array) rather than software. One or more functions of computer program components described herein may be software-implemented, hardware-implemented, or software and hardware-implemented.

Referring again to machine-readable instructions 40100 in FIG. 40A, the obtaining component 40102 may be configured to obtain values for a plurality of samples. The values correspond to a set of property parameters.

The identifying component 40104 may be configured to identify a first subset of property parameters from the set of property parameters that correlate to substantially all property parameters of the set of property parameters.

The generating component 40106 may be configured to generate at least one model using the first subset of property parameters and a database corresponding to the at least one model, and use the at least one model for generating a value for at least one other property parameter of the set of property parameters. The first subset of property parameters and the at least one other property parameter are different. The database may be stored in the electronic storage 4013 and the database may be accessible via the graphical display 4014.

The additional sample component 40108 may be configured to obtain a value for a particular parameter of the first subset of property parameters for an additional sample; and use the value for the particular parameter of the first subset of property parameters for the additional sample in the at least one model to generate a value for at least one other property for the additional sample.

The comparing component 40110 may be configured to compare the generated value for the at least one other property parameter for the additional sample to a measured value for the at least one other property parameter for the additional sample; and update the at least one model and the database corresponding to the at least one model using the measured value for the at least one other property parameter for the additional sample in response to the comparison.

The variate modelling component 40112 may be configured to: obtain values for a second plurality of samples, wherein the values correspond to a second set of property parameters and wherein at least some of the obtained values for the second plurality of samples are obtained from the database corresponding to the at least one model; perform bi-variate modelling on the second set of property parameters to generate bi-variate relationships for the second set of property parameters and selecting the bi-variate relationships that satisfy correlation criteria; perform multi-variate modelling on the property parameters corresponding to the unselected bi-variate relationships to generate multi-variate relationships for the unselected bi-variate relationships and selecting the multi-variate relationships that satisfy the correlation criteria; and combine the bi-variate models corresponding to the selected bi-variate relationships and the multi-variate models corresponding to the selected multi-variate relationships to generate a combined model comprising the corresponding parameters.

Turning to the machine-readable instructions 40100 in FIG. 40B, the obtaining component 50102 may be configured to obtain values for a plurality of samples. The values correspond to a set of property parameters.

The bi-variate modelling component 50104 may be configured to perform bi-variate modelling on the set of property parameters to generate bi-variate relationships for the set of property parameters and selecting the bi-variate relationships that satisfy correlation criteria.

The multi-variate modelling component 50106 may be configured to perform multi-variate modelling on the property parameters corresponding to the unselected bi-variate relationships to generate multi-variate relationships for the unselected bi-variate relationships and selecting the multi-variate relationships that satisfy the correlation criteria.

The combining component 50108 may be configured to combine the bi-variate models corresponding to the selected bi-variate relationships and the multi-variate models corresponding to the selected multi-variate relationships to generate a combined model comprising the corresponding parameters.

The pre-processing component 50110 may be configured to pre-process at least a portion of the obtained values for a plurality of samples before performing the bi-variate modelling. The pre-processing comprises labelling, transforming using a transformation algorithm, or any combination thereof.

The additional sample component 50112 may be configured to obtain a value for a particular parameter of the combined model for an additional sample; and use the value of the particular parameter for the additional sample in the combined model to generate a value for at least one other property parameter for the additional sample.

The description of the functionality provided by the different computer program components described herein is for illustrative purposes, and is not intended to be limiting, as any of computer program components may provide more or less functionality than is described. For example, one or more of computer program components may be eliminated, and some or all of its functionality may be provided by other computer program components. As another example, processor 4011 may be configured to execute one or more additional computer program components that may perform some or all of the functionality attributed to one or more of computer program components described herein.

While particular embodiments and examples are described above, it will be understood it is not intended to limit the invention to these particular embodiments. On the contrary, the invention includes alternatives, modifications and equivalents that are within the spirit and scope of the appended claims. Numerous specific details are set forth in order to provide a thorough understanding of the subject matter presented herein. But it will be apparent to one of ordinary skill in the art that the subject matter may be practiced without these specific details. In other instances, well-known methods, procedures, components, and circuits have not been described in detail so as not to unnecessarily obscure aspects of the embodiments.

Other definitions: The terms “comprise” (as well as forms, derivatives, or variations thereof, such as “comprising” and “comprises”) and “include” (as well as forms, derivatives, or variations thereof, such as “including” and “includes”) are inclusive (i.e., open-ended) and do not exclude additional elements or steps. For example, the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Accordingly, these terms are intended to not only cover the recited element(s) or step(s), but may also include other elements or steps not expressly recited. Furthermore, as used herein, the use of the terms “a” or “an” when used in conjunction with an element may mean “one,” but it is also consistent with the meaning of “one or more,” “at least one,” and “one or more than one.” Therefore, an element preceded by “a” or “an” does not, without more constraints, preclude the existence of additional identical elements. It will also be understood that the term “and/or” as used herein refers to and encompasses any and all possible combinations of one or more of the associated listed items.

The use of the term “about” applies to all numeric values, whether or not explicitly indicated. This term generally refers to a range of numbers that one of ordinary skill in the art would consider as a reasonable amount of deviation to the recited numeric values (i.e., having the equivalent function or result). For example, this term can be construed as including a deviation of ±10 percent of the given numeric value provided such a deviation does not alter the end function or result of the value. Therefore, a value of about 1% can be construed to be a range from 0.9% to 1.1%. Furthermore, a range may be construed to include the start and the end of the range. For example, a range of 10% to 20% (i.e., range of 10%-20%) includes 10% and also includes 20%, and includes percentages in between 10% and 20%, unless explicitly stated otherwise herein. Similarly, a range of between 10% and 20% (i.e., range between 10%-20%) includes 10% and also includes 20%, and includes percentages in between 10% and 20%, unless explicitly stated otherwise herein.

The term “if” may be construed to mean “when” or “upon” or “in response to determining” or “in accordance with a determination” or “in response to detecting,” that a stated condition precedent is true, depending on the context. Similarly, the phrase “if it is determined [that a stated condition precedent is true]” or “if [a stated condition precedent is true]” or “when [a stated condition precedent is true]” may be construed to mean “upon determining” or “in response to determining” or “in accordance with a determination” or “upon detecting” or “in response to detecting” that the stated condition precedent is true, depending on the context.

The term “obtaining” may include receiving, retrieving, accessing, generating, etc. or any other manner of obtaining data.

It is understood that when combinations, subsets, groups, etc. of elements are disclosed (e.g., combinations of components in a composition, or combinations of steps in a method), that while specific reference of each of the various individual and collective combinations and permutations of these elements may not be explicitly disclosed, each is specifically contemplated and described herein. By way of example, if an item is described herein as including a component of type A, a component of type B, a component of type C, or any combination thereof, it is understood that this phrase describes all of the various individual and collective combinations and permutations of these components. For example, in some embodiments, the item described by this phrase could include only a component of type A. In some embodiments, the item described by this phrase could include only a component of type B. In some embodiments, the item described by this phrase could include only a component of type C. In some embodiments, the item described by this phrase could include a component of type A and a component of type B. In some embodiments, the item described by this phrase could include a component of type A and a component of type C. In some embodiments, the item described by this phrase could include a component of type B and a component of type C. In some embodiments, the item described by this phrase could include a component of type A, a component of type B, and a component of type C. In some embodiments, the item described by this phrase could include two or more components of type A (e.g., A1 and A2). In some embodiments, the item described by this phrase could include two or more components of type B (e.g., B1 and B2). In some embodiments, the item described by this phrase could include two or more components of type C (e.g., C1 and C2). In some embodiments, the item described by this phrase could include two or more of a first component (e.g., two or more components of type A (A1 and A2)), optionally one or more of a second component (e.g., optionally one or more components of type B), and optionally one or more of a third component (e.g., optionally one or more components of type C). In some embodiments, the item described by this phrase could include two or more of a first component (e.g., two or more components of type B (B1 and B2)), optionally one or more of a second component (e.g., optionally one or more components of type A), and optionally one or more of a third component (e.g., optionally one or more components of type C). In some embodiments, the item described by this phrase could include two or more of a first component (e.g., two or more components of type C (C1 and C2)), optionally one or more of a second component (e.g., optionally one or more components of type A), and optionally one or more of a third component (e.g., optionally one or more components of type B).

This written description uses examples to disclose the invention, including the best mode, and also to enable any person skilled in the art to make and use the invention. The patentable scope is defined by the claims, and may include other examples that occur to those skilled in the art. Such other examples are intended to be within the scope of the claims if they have elements that do not differ from the literal language of the claims, or if they include equivalent elements with insubstantial differences from the literal language of the claims.

Unless defined otherwise, all technical and scientific terms used herein have the same meanings as commonly understood by one of skill in the art to which the disclosed invention belongs. All citations referred herein are expressly incorporated by reference.

Although some of the various drawings illustrate a number of logical stages in a particular order, stages that are not order dependent may be reordered and other stages may be combined or broken out. While some reordering or other groupings are specifically mentioned, others will be obvious to those of ordinary skill in the art and so do not present an exhaustive list of alternatives. Moreover, it should be recognized that the stages could be implemented in hardware, firmware, software or any combination thereof.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as are suited to the particular use contemplated.

What is claimed is:

1. A method of generating values for property parameters, the method comprising:
obtaining values for a plurality of samples, wherein the values correspond to a set of property parameters;
identifying a first subset of property parameters from the set of property parameters that correlate to substantially all property parameters of the set of property parameters; and
generating at least one model using the first subset of property parameters and a database corresponding to the at least one model, and using the at least one model for generating a value for at least one other property parameter of the set of property parameters, wherein the first subset of property parameters and the at least one other property parameter are different.

2. The method of claim 1, wherein the values are obtained for a plurality of fluid samples, and wherein the values correspond to a set of fluid property parameters.

3. The method of claim 2, wherein the plurality of fluid samples comprises an oil sample from a separator, a gas sample from a separator, or any combination thereof.

4. The method of claim 1, wherein the values are obtained for a plurality of fluid samples and solid samples, and wherein the values correspond to a set of fluid and solid property parameters.

5. The method of claim 4, wherein the plurality of fluid samples and solid samples comprises an oil sample from a separator, a gas sample from a separator, or any combination thereof.

6. The method of claim 1, wherein the values are obtained for a plurality of solid samples, and wherein the values correspond to a set of solid property parameters.

7. The method of claim 1, wherein at least a portion of the obtained values for the plurality of samples satisfy quality criteria; and
wherein the quality criteria comprises measurement error, first principles, constraint by physics of a subsurface region, acquisition of the plurality of samples, thermodynamic consistency of the plurality of samples, quantity of the plurality of samples, or any combination thereof.

8. The method of claim 1, wherein identifying the first subset of property parameters from the set of property parameters that correlate to substantially all property parameters of the set of property parameters comprises using correlation criteria.

9. The method of claim 8, wherein the correlation criteria comprises correlation factor, model fitness, trend analysis, constraint by physics of a subsurface region, or any combination thereof.

10. The method of claim 1, wherein identifying the first subset of property parameters from the set of property parameters that correlate to substantially all property parameters of the set of property parameters comprises transposing the obtained values for the plurality of samples, using a pairwise correlation matrix, or any combination thereof.

11. The method of claim 1, wherein generating the at least one model using the first subset of property parameters comprises generating at least one best-fit model using the first subset of property parameters.

12. The method of claim 1, wherein generating the at least one model using the first subset of property parameters comprises using a machine learning algorithm to search for at least one best fit model; and
wherein the machine learning algorithm comprises: Genetic Algorithm (GA), Evolution Strategy (ES), Genetic Programming (GP), Biogeography Based Optimizer (BBO), Evolutionary Programming (EP), Simulated Annealing (SA), Gravitational Search Algorithm (GSA), Charged System Search (CSS), Central Force Optimization (CFO), Black Hole Algorithm (BH), Particle Swarm Optimization (PSO), Crow Search Algorithm (CSA), Dragonfly Algorithm (DA), Artificial Bee Colony (ABC), Cuckook Search (CS), Moth Swam Algorithm (MSA), Ant Colony Optimization Algorithm (ACO), Grey Wolf Optimization Algorithm (GWO), Stochastic Fractal Search (SFS), Sine Cosine Algorithm (SCA), Water Cycle Algorithm (WCA), Whale Optimization Algorithm (WOA), Bat Algorithm (BA), or any combination thereof.

13. The method of claim 1, wherein generating the at least one model using the first subset of property parameters comprises using a machine learning algorithm to perform regression; and
wherein the machine learning algorithm comprises: Ordinary Least Square Regression (OLSR), Linear Regression, Polynomial Regression, Stepwise Regression, Multivariate Adaptive Regression Splines (MARS), Random Forest, Neural Network, Gradient Boosting Machines (GBM), Gradient Boosted Regression Trees (GBRT), Locally Estimated Scatterplot Smoothing (LOESS), Jacknife Regression, Ridge Regression, Lease Absolute Shrinkage and Selection Operator (LASSO), Elastic Net, Lease-Angle Regression (LARS), Support Vector Machine (SVM), Classification and Regression Tree (CART), or any combination thereof.

14. The method of claim 1, further comprising:
obtaining a value for a particular parameter of the first subset of property parameters for an additional sample; and
using the value for the particular parameter of the first subset of property parameters for the additional sample in the at least one model to generate a value for at least one other property for the additional sample.

15. The method of claim 14, wherein a value for GOR is generated for the additional sample, a value for PVT is generated for the additional sample, a value for viscosity is generated for the additional sample, a value for composition is generated for the additional sample, or any combination thereof.

16. The method of claim 14, further comprising:
comparing the generated value for the at least one other property parameter for the additional sample to a measured value for the at least one other property parameter for the additional sample; and
updating the at least one model and the database corresponding to the at least one model using the measured value for the at least one other property parameter for the additional sample in response to the comparison.

17. The method of claim 14, wherein the at least one model and the database corresponding to the at least one model are updated if an absolute difference between the generated value and the measured value is less than about 20%.

18. The method of claim 1, further comprising:
obtaining values for a second plurality of samples, wherein the values correspond to a second set of property parameters and wherein at least some of the obtained values for the second plurality of samples are obtained from the database corresponding to the at least one model;
performing bi-variate modelling on the second set of property parameters to generate bi-variate relationships for the second set of property parameters and selecting the bi-variate relationships that satisfy correlation criteria;
performing multi-variate modelling on the property parameters corresponding to the unselected bi-variate relationships to generate multi-variate relationships for the unselected bi-variate relationships and selecting the multi-variate relationships that satisfy the correlation criteria; and
combining the bi-variate models corresponding to the selected bi-variate relationships and the multi-variate models corresponding to the selected multi-variate relationships to generate a combined model comprising the corresponding parameters.

19. The method of claim 18, wherein the obtained values for the second plurality of samples and the second set of property parameters are substantially the same as those in claim 1.

20. A system of generating values for property parameters, the system comprising:
one or more physical processors configured by machine-readable instructions to execute the method of:
obtaining values for a plurality of samples, wherein the values correspond to a set of property parameters;
identifying a first subset of property parameters from the set of property parameters that correlate to substantially all property parameters of the set of property parameters; and
generating at least one model using the first subset of property parameters and a database corresponding to the at least one model, and using the at least one model for generating a value for at least one other property parameter of the set of property parameters, wherein the first subset of property parameters and the at least one other property parameter are different.

21. A non-transitory computer readable storage medium storing one or more programs, the one or more programs comprising instructions, which when executed by an electronic device with one or more processors and memory, cause the device to execute the method of:
obtaining values for a plurality of samples, wherein the values correspond to a set of property parameters;
identifying a first subset of property parameters from the set of property parameters that correlate to substantially all property parameters of the set of property parameters; and
generating at least one model using the first subset of property parameters and a database corresponding to the at least one model, and using the at least one model for generating a value for at least one other property parameter of the set of property parameters, wherein the first subset of property parameters and the at least one other property parameter are different.
